(19) United States
(12) Patent Application Publication
(10) Pub. No.: US 2019/0279924 A1
(43) Pub. Date: Sep. 12, 2019

(54) SEMICONDUCTOR PACKAGE STRUCTURE AND METHOD OF MANUFACTURING THE SAME

(71) Applicant: Advanced Semiconductor Engineering, Inc., Kaohsiung (TW)

(72) Inventors: Bernd Karl APPELT, Kaohsiung (TW); You-Lung YEN, Kaohsiung (TW)

(73) Assignee: Advanced Semiconductor Engineering, Inc., Kaohsiung (TW)

(21) Appl. No.: 15/917,509

(22) Filed: Mar. 9, 2018

(51) Int. Cl. H01L 23/498; H01L 23/31; H01L 23/29; H01L 23/00; H01L 25/10; H01L 25/065; H01L 25/16

(52) U.S. Cl. CPC H01L 23/49811; H01L 2225/06513; H01L 23/3121; H01L 23/295; H01L 23/49838; H01L 24/73; H01L 24/17; H01L 25/105; H01L 25/0657; H01L 25/16; H01L 2224/73265; H01L 2924/014; H01L 2225/1058; H01L 2225/0651; H01L 2225/06517; H01L 23/49827

(57) ABSTRACT

A semiconductor package structure includes a first patterned conductive layer including a first conductive pad, a second conductive pad and a first conductive trace disposed between the first conductive pad and the second first conductive pad. The first conductive pad defines a recess. The semiconductor package structure further includes a second patterned conductive layer including a third conductive pad. The semiconductor package structure further includes a first stud bump electrically connecting the first conductive pad of the first patterned conductive layer to the third conductive pad of the second patterned conductive layer. The semiconductor package structure further includes a first encapsulation layer disposed between the first patterned conductive layer and the second patterned conductive layer.

### TECHNICAL FIELD

The present disclosure generally relates to a semiconductor package structure, and to a method of manufacturing the same.

### BACKGROUND

Coreless substrates and substrates including conductive interconnections encapsulated by a molding compound (or an encapsulant) can be used in a semiconductor device package. Coreless substrates may reduce an overall thickness of a semiconductor device package. However, due to a lack of core material, warpage issues may occur in the process of manufacturing the semiconductor device package. As to the substrate having conductive interconnections encapsulated by an encapsulant, conductive interconnections may be formed in the substrate by a laser drilling technique and a plating technique. However, the encapsulant may be damaged during the process of manufacturing the semiconductor device package. Moreover, issues may occur in the process of manufacturing the semiconductor device package.

### SUMMARY

In some embodiments, according to one aspect, a semiconductor package structure includes a first patterned conductive layer including a first conductive pad, a second conductive pad and a first conductive trace disposed between the first conductive pad and the second first conductive pad. The first conductive pad defines a recess. The semiconductor package structure further includes a second patterned conductive layer including a third conductive pad. The semiconductor package structure further includes a first stud bump electrically connecting the first conductive pad of the first patterned conductive layer to the first conductive pad of the second patterned conductive layer. The semiconductor package structure further includes a first encapsulation layer disposed between the first patterned conductive layer and the second patterned conductive layer.

In some embodiments, according to another aspect, a semiconductor package structure includes a first substrate, a first encapsulation layer disposed on the first substrate, a first patterned conductive layer including a first conductive pad, a second patterned conductive layer and a first stud bump. The first encapsulation layer has a first surface and a second surface opposite to the first surface. The first patterned conductive layer is embedded in the first surface of the first encapsulation layer and the second patterned conductive layer is embedded in the second surface of the first encapsulation layer. The first conductive pad of the first patterned conductive layer defines a recess, and the first stud bump electrically connects the first conductive pad of the first patterned conductive layer to a portion of the second patterned conductive layer.

In some embodiments, according to another aspect, a method for manufacturing a semiconductor package structure includes providing a first carrier and a first patterned conductive layer disposed on the first carrier; the first patterned conductive layer including a first conductive pad. The method further includes forming a first stud bump on the first conductive pad of the first patterned conductive layer and providing a first electrical connection element on one end of the first stud bump. The method further includes providing a second carrier including a second patterned conductive layer disposed on the second carrier, the second patterned conductive layer including a second conductive pad having defining recess. The method further includes attaching the first carrier and the second carrier together such that the first electrical connection element is disposed within the recess of the second conductive pad of the second patterned conductive layer and forming a first encapsulation layer between the first carrier and the second carrier.

### BRIEF DESCRIPTION OF THE DRAWINGS

Aspects of the present disclosure are readily understood from the following detailed description when read with the accompanying figures. It is noted that various features may not be drawn to scale, and the dimensions of the various features may be arbitrarily increased or reduced for clarity of discussion.

FIG. 1 is a schematic diagram illustrating a cross-sectional view of a semiconductor package structure according to some embodiments of the present disclosure.

FIG. 1A is a schematic diagram illustrating a cross-sectional view of a semiconductor package structure according to some embodiments of the present disclosure.

FIG. 1B is a schematic diagram illustrating a cross-sectional view of a semiconductor package structure according to some embodiments of the present disclosure.

FIG. 1C is a schematic diagram illustrating a cross-sectional view of a semiconductor package structure according to some embodiments of the present disclosure.

FIG. 1D is a schematic diagram illustrating a cross-sectional view of a semiconductor package structure according to some embodiments of the present disclosure.

FIG. 1E is a schematic diagram illustrating a cross-sectional view of a semiconductor package structure according to some embodiments of the present disclosure.

FIG. 2 is a schematic diagram illustrating a cross-sectional view of a semiconductor package structure according to some embodiments of the present disclosure.

FIG. 2A is a schematic diagram illustrating a cross-sectional view of a semiconductor package structure according to some embodiments of the present disclosure.

FIG. 2B is a schematic diagram illustrating a cross-sectional view of a semiconductor package structure according to some embodiments of the present disclosure.

FIG. 2C is a schematic diagram illustrating a cross-sectional view of a semiconductor package structure according to some embodiments of the present disclosure.

FIG. 2D is a schematic diagram illustrating a cross-sectional view of a semiconductor package structure according to some embodiments of the present disclosure.

FIG. 2E is a schematic diagram illustrating a cross-sectional view of a semiconductor package structure according to some embodiments of the present disclosure.

FIG. 3 is a schematic diagram illustrating a cross-sectional view of a semiconductor package structure according to some embodiments of the present disclosure.

FIG. 3A is a schematic diagram illustrating a cross-sectional view of a semiconductor package structure according to some embodiments of the present disclosure.

FIG. 3B is a schematic diagram illustrating a cross-sectional view of a semiconductor package structure according to some embodiments of the present disclosure.

FIG. 3C is a schematic diagram illustrating a cross-sectional view of a semiconductor package structure according to some embodiments of the present disclosure.

FIG. 3D is a schematic diagram illustrating a cross-sectional view of a semiconductor package structure according to some embodiments of the present disclosure.

FIG. 3E is a schematic diagram illustrating a cross-sectional view of a semiconductor package structure according to some embodiments of the present disclosure.

FIG. 4 is a schematic diagram illustrating a cross-sectional view of a semiconductor package structure according to some embodiments of the present disclosure.

FIG. 4A is a schematic diagram illustrating a cross-sectional view of a semiconductor package structure according to some embodiments of the present disclosure.

FIG. 4B is a schematic diagram illustrating a cross-sectional view of a semiconductor package structure according to some embodiments of the present disclosure.

FIG. 4C is a schematic diagram illustrating a cross-sectional view of a semiconductor package structure according to some embodiments of the present disclosure.

FIG. 4D is a schematic diagram illustrating a cross-sectional view of a semiconductor package structure according to some embodiments of the present disclosure.

FIG. 4E is a schematic diagram illustrating a cross-sectional view of a semiconductor package structure according to some embodiments of the present disclosure.

FIG. 4F is a schematic diagram illustrating a cross-sectional view of a semiconductor package structure according to some embodiments of the present disclosure.

FIG. 4G is a schematic diagram illustrating a cross-sectional view of a semiconductor package structure according to some embodiments of the present disclosure.

FIG. 5A is a schematic diagram illustrating a cross-sectional view of a semiconductor package structure according to some embodiments of the present disclosure.

FIG. 5B is a schematic diagram illustrating a cross-sectional view of a semiconductor package structure according to some embodiments of the present disclosure.

FIG. 5C is a schematic diagram illustrating a cross-sectional view of a semiconductor package structure according to some embodiments of the present disclosure.

FIG. 5D is a schematic diagram illustrating a cross-sectional view of a semiconductor package structure according to some embodiments of the present disclosure.

FIG. 5E is a schematic diagram illustrating a cross-sectional view of a semiconductor package structure according to some embodiments of the present disclosure.

FIG. 5F is a schematic diagram illustrating a cross-sectional view of a semiconductor package structure according to some embodiments of the present disclosure.

FIG. 5G is a schematic diagram illustrating a cross-sectional view of a semiconductor package structure according to some embodiments of the present disclosure.

FIG. 6A is a schematic diagram illustrating a cross-sectional view of a semiconductor package structure according to some embodiments of the present disclosure.

FIG. 6B is a schematic diagram illustrating a cross-sectional view of a semiconductor package structure according to some embodiments of the present disclosure.

FIG. 6C is a schematic diagram illustrating a cross-sectional view of a semiconductor package structure according to some embodiments of the present disclosure.

FIG. 6D is a schematic diagram illustrating a cross-sectional view of a semiconductor package structure according to some embodiments of the present disclosure.

FIG. 6E is a schematic diagram illustrating a cross-sectional view of a semiconductor package structure according to some embodiments of the present disclosure.

FIG. 7A is a schematic diagram illustrating a cross-sectional view of a semiconductor package structure according to some embodiments of the present disclosure.

FIG. 7B is a schematic diagram illustrating a cross-sectional view of a semiconductor package structure according to some embodiments of the present disclosure.

FIG. 8A, FIG. 8B, FIG. 8C, FIG. 8D, FIG. 8E, FIG. 8F, FIG. 8G, FIG. 8H, FIG. 8I, and FIG. 8J illustrate a method of manufacturing a semiconductor package structure according to some embodiments of the present disclosure. FIG. 8K and 8L illustrate operations of a comparative method of manufacturing a semiconductor package structure.

FIG. 9A, FIG. 9B, FIG. 9C, FIG. 9D, FIG. 9E, and FIG. 9F illustrate a method of manufacturing a semiconductor package structure according to some embodiments of the present disclosure.

FIG. 10A, FIG. 10B, FIG. 10C, FIG. 10D, FIG. 10E, and FIG. 10F illustrate a method of manufacturing a semiconductor package structure according to some embodiments of the present disclosure.

FIG. 11A, FIG. 11B, FIG. 11C, FIG. 11D, FIG. 11E, and FIG. 11F illustrate a method of manufacturing a semiconductor package structure according to some embodiments of the present disclosure.

FIG. 12A, FIG. 12B, FIG. 12C, FIG. 12D, FIG. 12E, FIG. 12F, FIG. 12G, FIG. 12H, FIG. 12I, and FIG. 12J illustrate a method of manufacturing a semiconductor package structure according to some embodiments of the present disclosure.

FIG. 13A, FIG. 13B, and FIG. 13C illustrate a method of manufacturing a semiconductor package structure according to some embodiments of the present disclosure.

FIG. 14A, FIG. 14B, and FIG. 14C illustrate a method of manufacturing a semiconductor package structure according to some embodiments of the present disclosure.

FIG. 15A and FIG. 15B illustrate a method of manufacturing a semiconductor package structure according to some embodiments of the present disclosure.

FIG. 16A, FIG. 16B, and FIG. 16C illustrate a method of manufacturing a semiconductor package structure according to some embodiments of the present disclosure.

### DETAILED DESCRIPTION

Embodiments of the present disclosure and use thereof are discussed in detail below. It should be appreciated, however, that the embodiments set forth many applicable concepts that can be embodied in a wide variety of specific contexts. It is to be understood that the following disclosure provides for many different embodiments or examples of implementing different features of various embodiments. Specific examples of components and arrangements are described below for purposes of discussion. These are, of course, merely examples and are not intended to be limiting.

Spatial descriptions, including such terms as “above,” “below,” “up,” “left,” “right,” “down,” “top,” “bottom,” “vertical,” “horizontal,” “side,” “higher,” “lower,” “upper,” “over,” “under,” and so forth, are used herein with respect to an orientation shown in corresponding figures unless otherwise specified. It should be understood that the spatial descriptions used herein are for purposes of illustration, and that practical implementations of the structures described herein can be spatially arranged in any orientation or manner, provided that the merits of embodiments of this disclosure are not deviated from by such arrangement.

Embodiments, or examples, illustrated in the figures are disclosed below using specific language. It will nevertheless be understood that the embodiments and examples are not intended to be limiting. Any alterations and modifications of the disclosed embodiments, and any further applications of the principles disclosed in this document, as would normally occur to one of ordinary skill in the pertinent art, fall within the scope of this disclosure.

In addition, the present disclosure may repeat reference numerals and/or letters in the various examples. This repetition is for the purpose of simplicity and clarity and does not in itself dictate a relationship between the various embodiments and/or configurations discussed herein.

The present disclosure provides for a packaging method and a packaging structure. In one or more methods and structures described herein, lamination of a dielectric material on a substrate may be omitted and thus a cost for manufacturing the packaging structures may be reduced. Embodiments of methods disclosed in the present disclosure can increase a substrate yield and can also provide for a reduced overall thickness of a package. In addition, reliability of a package manufactured using the method disclosed in the present disclosure can be enhanced.

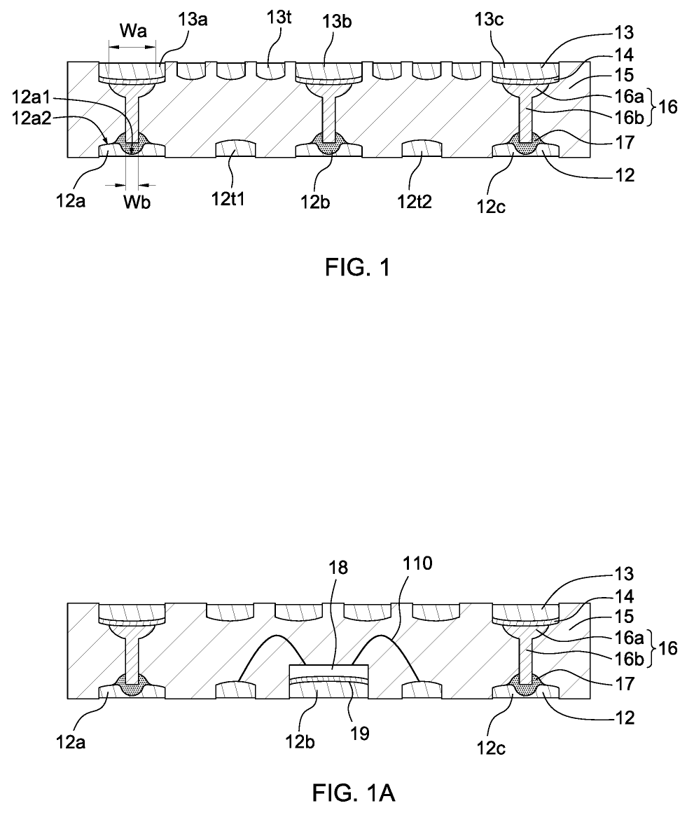

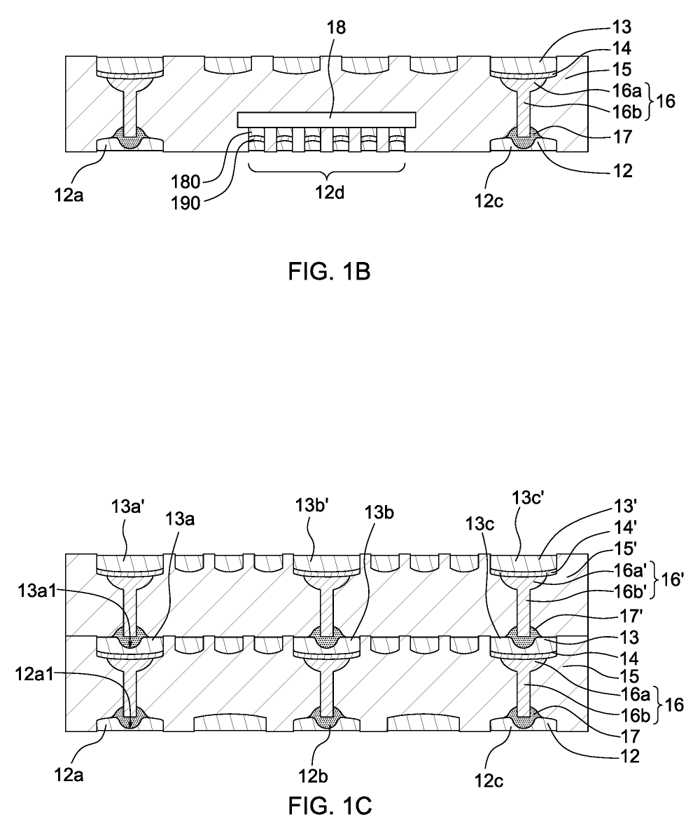

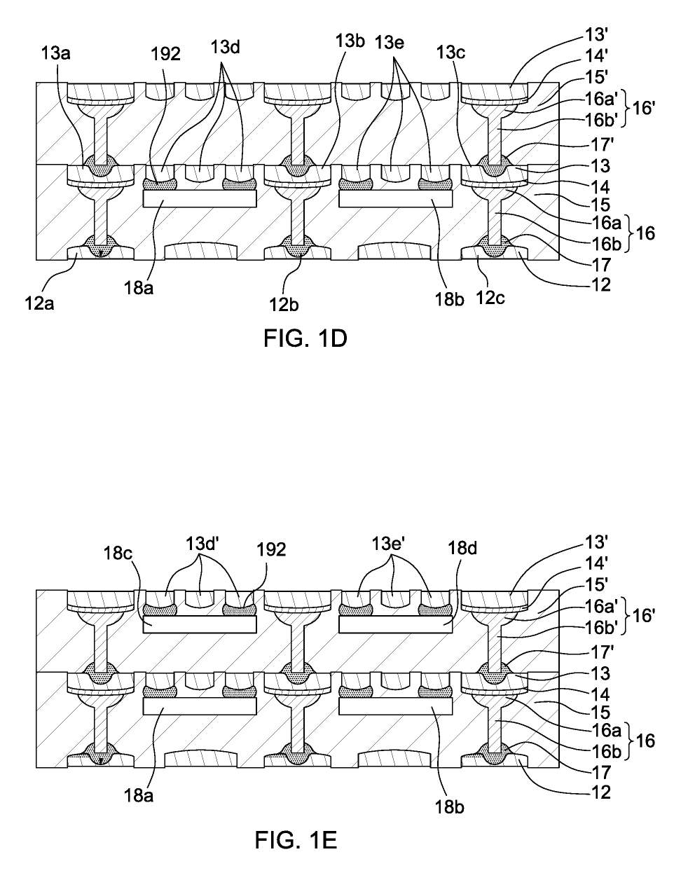

FIG. 1 is a schematic diagram illustrating a cross-sectional view of a semiconductor package structure according to some embodiments of the present disclosure. As shown in FIG. 1, the semiconductor package structure includes a patterned conductive layer 12, a patterned conductive layer 13, a metal finishing layer 14, an encapsulation layer 15, a stud bump 16 and an electrical connection element 17.

The patterned conductive layer 12 includes conductive pads 12a, 12b and 12c. In some embodiments, the patterned conductive layer 12 further includes a conductive trace 12t1 disposed between the conductive pads 12a and 12b. In some embodiments, the patterned conductive layer 12 further includes a conductive trace 12t2 disposed between the conductive pads 12b and 12c. The patterned conductive layer 13 includes one or more conductive pads 13a, 13b and 13c. The patterned conductive layer 13 may further include one or more conductive traces 13t disposed between the conductive pads. While traces and pads are depicted with a domed top, in one or more embodiments they may be substantially planar. The stud bump 16 includes a bump portion 16a and a stud portion 16b. A width Wa of the bump portion 16a is greater than a width Wb of the stud portion 16b (e.g. by a factor of about 1.2 or more, about 1.5 or more, or about 2.0 or more).

The conductive pad 12a includes a portion 12a1 and a portion 12a2. In some embodiments, the portion 12a1 defines a recess, a dimple, or a cup shape. The portion 12a1 may be referred to herein as a “recess portion.” The conductive pads 12b and 12c are substantially in the same shape as the conductive pad 12a. The encapsulation layer 15 encapsulates the patterned conductive layer 12, the patterned conductive layer 13, the metal finishing layer 14, the stud bump 16 and the electrical connection element 17. The encapsulation layer 15 may include an epoxy, a filler, or other suitable materials.

The metal finishing layer 14 is disposed on the patterned conductive layer 13. The bump portion 16a is electrically connected to (and, for example, in contact with) the metal finishing layer 14, and the stud portion 16b is electrically connected to (and, for example, in contact with) the electrical connection element 17. In some embodiments, the metal finishing layer 14 may be omitted so that the bump portion 16a is electrically connected to (and, for example, in contact with) a conductive pad of the patterned conductive layer 13. The electrical connection element 17 is disposed within the portion 12a1 (e.g. within the recess defined by the portion 12a1) and is electrically connected to (and, for example, in contact with) the conductive pad 12a. In some embodiments, the electrical connection elements 17 may include solder material, for example, tin (Sn), another metal or other suitable material. Although not shown in FIG. 1, in some embodiments, an intermetallic compound is formed between the electrical connection element 17 and the portion 12a1 and also between 17 and a portion of stud bump 16b. In some embodiments, external surfaces of traces 12t and 13t can be protected by a dielectric coating like a solder mask or the like. External surfaces of pads 12 and 13 can have surface finishes appropriate for external connections (e.g. OSP (organic solder preservative), NiAu (nickel gold alloy), Pd (palladium), Ag (silver), Sn, solder, or other suitable material). Neither are shown here or in the other figures for sake of simplicity.

FIG. 1A is a schematic diagram illustrating a cross-sectional view of a semiconductor package structure according to some embodiments of the present disclosure. The semiconductor package structure shown in FIG. 1A is similar to the semiconductor package structure shown in FIG. 1, except that the conductive pad 12b does not define a recess portion, and that the stud bump 16 and the electrical connection element 17 above the conductive pad 12b are replaced by a die 18. The back surface of the die 18 is attached to the conductive pad 12b via an adhesive layer 19. The active surface of the die 18 is electrically connected to the patterned conductive layer 12 via a wire connection 110. Further details of die, wire connection and pads have been omitted for simplicity.

FIG. 1B is a schematic diagram illustrating a cross-sectional view of a semiconductor package structure according to some embodiments of the present disclosure. The semiconductor package structure shown in FIG. 1B is similar to the semiconductor package structure shown in FIG. 1, except that the conductive pad 12b is replaced by a plurality of conductive pads 12d and that a die 18 is mounted on the conductive pads 12d. As shown in FIG. 1B, the die 18 includes a plurality of connection pins 180. The plurality of connection pins 180 are electrically connected to the conductive pads 12d through electrical connection elements 190. The connection pins may also be solder bumps or spheres.

FIG. 1C is a schematic diagram illustrating a cross-sectional view of a semiconductor package structure according to some embodiments of the present disclosure. As shown in FIG. 1C, the semiconductor package structure includes a patterned conductive layer 12, a patterned conductive layer 13, a patterned conductive layer 13′, a metal finishing layer 14, a metal finishing layer 14′, an encapsulation layer 15, an encapsulation layer 15′, a stud bump 16, a stud bump 16′, an electrical connection element 17 and an electrical connection element 17′.

The patterned conductive layer 12 includes conductive pads 12a, 12b and 12c. The patterned conductive layer 12 may further include one or more traces disposed between the conductive pads. The patterned conductive layer 13 includes conductive pads 13a, 13b and 13c. The patterned conductive layer 13 may further include one or more traces disposed between the conductive pads. The patterned conductive layer 13′ includes conductive pads 13a′, 13b′ and 13c′ and one or more traces disposed between the conductive pads. The conductive pads 12a, 12b and 12c are in the same shape as those shown in FIG. 1. The conductive pads 13a, 13b and 13c are substantially in the same shape as the conductive pads 12a, 12b and 12c. The stud bump 16 includes a bump portion 16a and a stud portion 16b. The width of the bump portion 16a is greater than the width of the stud portion 16b (e.g. by a factor of about 1.2 or more, about 1.5 or more, or about 2.0 or more). The stud bump 16′ includes a bump portion 16a′ and a stud portion 16b′. The stud bump 16′ is substantially in the same shape as the stud bump 16.

The encapsulation layer 15 encapsulates the patterned conductive layer 12, the patterned conductive layer 13, the metal finishing layer 14, the stud bump 16 and the electrical connection element 17. The encapsulation layer 15′ encapsulates the patterned conductive layer 13′, the metal finishing layer 14′, the stud bump 16′ and the electrical connection element 17′. The encapsulation layer 15 and/or the encapsulation layer 15′ may include an epoxy, a filler, or other suitable materials. The metal finishing layer 14 is disposed on the patterned conductive layer 13 and the metal finishing layer 14′ is disposed on the patterned conductive layer 13′. The bump portion 16a is electrically connected to (and, for example in contact with) the metal finishing layer 14, and the stud portion 16b is electrically connected to (and, for example in contact with) the electrical connection element 17. In some embodiments, the metal finishing layer 14 may be omitted so that the bump portion 16a is electrically connected to (and, for example in contact with) a conductive pad of the patterned conductive layer 13. The bump portion 16a′ is electrically connected to (and, for example in contact with) the metal finishing layer 14′, and the stud portion 16b′ is electrically connected to (and, for example in contact with) the electrical connection element 17′. In some embodiments, the metal finishing layer 14′ may be omitted so that the bump portion 16a′ is electrically connected to (and, for example in contact with) a conductive pad of the patterned conductive layer 13′. The electrical connection element 17 is disposed within the portion 12a1 (e.g. within the recess defined by the portion 12a1) and is electrically connected to (and, for example in contact with) the conductive pad 12a. The electrical connection element 17′ is disposed within the portion 13a1 (e.g. within the recess defined by the portion 13a1) and is electrically connected to (and, for example in contact with) the conductive pad 13a. In some embodiments, the electrical connection elements 17 and 17′ may include solder material, for example, tin (Sn), another metal or other suitable material.

Although not shown in FIG. 1C, in some embodiments, an intermetallic compound is formed between the electrical connection element 17 and the portion 12a1, and an intermetallic compound is formed between the electrical connection element 17′ and the portion 13a1 and also between 17 and a portion of stud bump 16b.

FIG. 1D is a schematic diagram illustrating a cross-sectional view of a semiconductor package structure according to some embodiments of the present disclosure. The semiconductor package structure shown in FIG. 1D is similar to the semiconductor package structure shown in FIG. 1C, except that the semiconductor package structure shown in FIG. 1D further includes dies 18a and 18b. Alternatively one or both dies may be replaced by passive elements, such as resistors, capacitors or inductors. The dies 18a and 18b are respectively electrically connected to conductive pads 13d and 13e (e.g. pads of the patterned conductive layer 13) through electrical connection elements 192. The electrical connection elements 192 may be solder spheres, solder bumps, or studs with solder connections. As shown in FIG. 1D, the encapsulation layer 15 encapsulates the patterned conductive layer 12, the patterned conductive layer 13, the metal finishing layer 14, the stud bump 16, the electrical connection element 17 and the dies 18a and 18b.

FIG. 1E is a schematic diagram illustrating a cross-sectional view of a semiconductor package structure according to some embodiments of the present disclosure. The semiconductor package structure shown in FIG. 1E is similar to the semiconductor package structure shown in FIG. 1D, except that the semiconductor package structure shown in FIG. 1E further includes dies 18c and 18d. Alternatively one or both dies may be replaced by passive elements, such as resistors, capacitors or inductors. The dies 18c and 18d are respectively electrically connected to conductive pads 13d′ and 13e′ (e.g. pads of the patterned conductive layer 13′) through electrical connection elements 192. The electrical connection elements 192 may be solder spheres, solder bumps, or studs with solder connections. As shown in FIG. 1E, the encapsulation layer 15′ encapsulates the patterned conductive layer 13′, the metal finishing layer 14′, the stud bump 16′, the electrical connection element 17′ and the dies 18c and 18d.

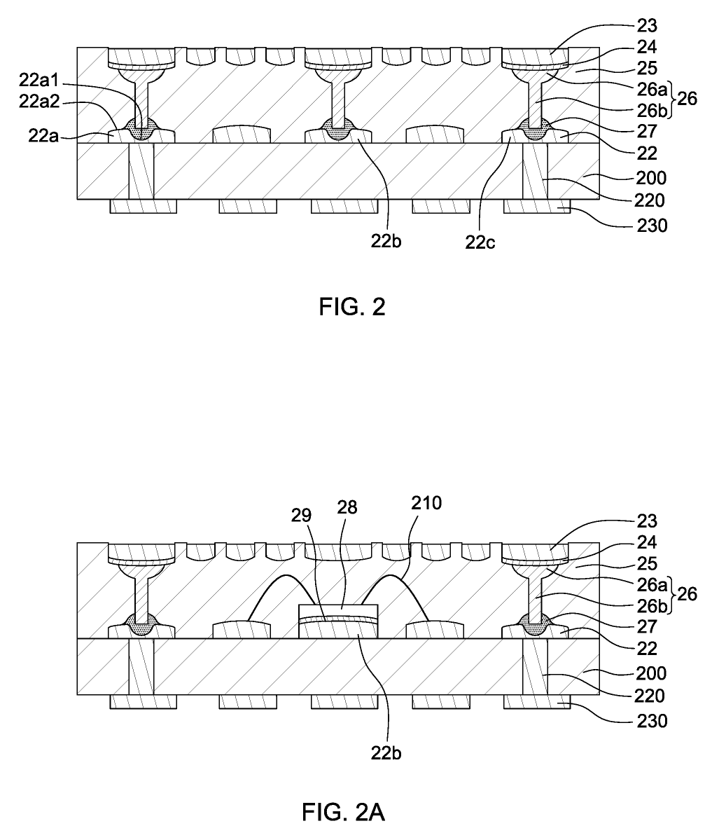

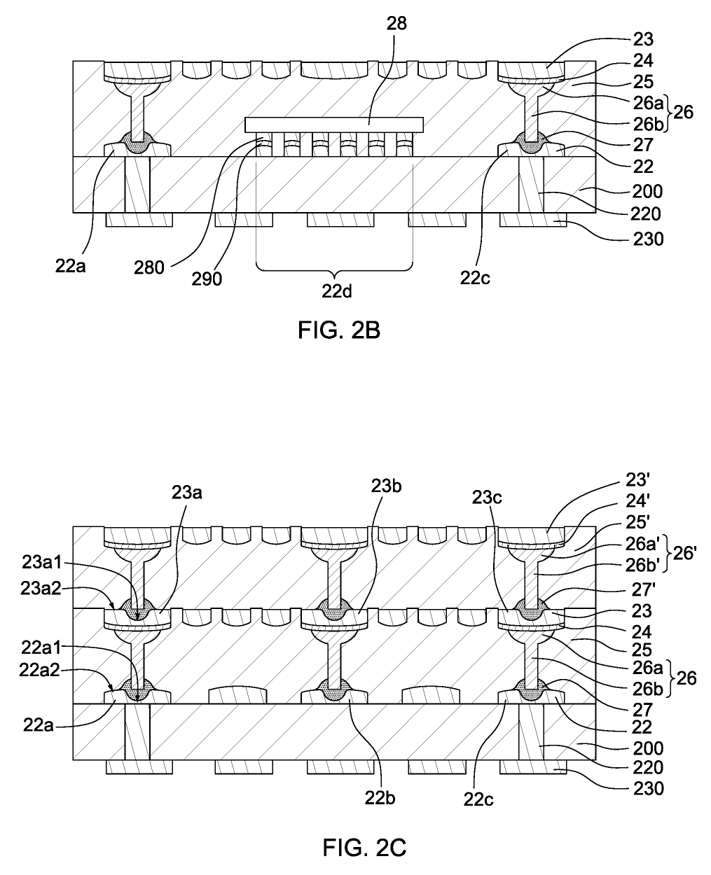

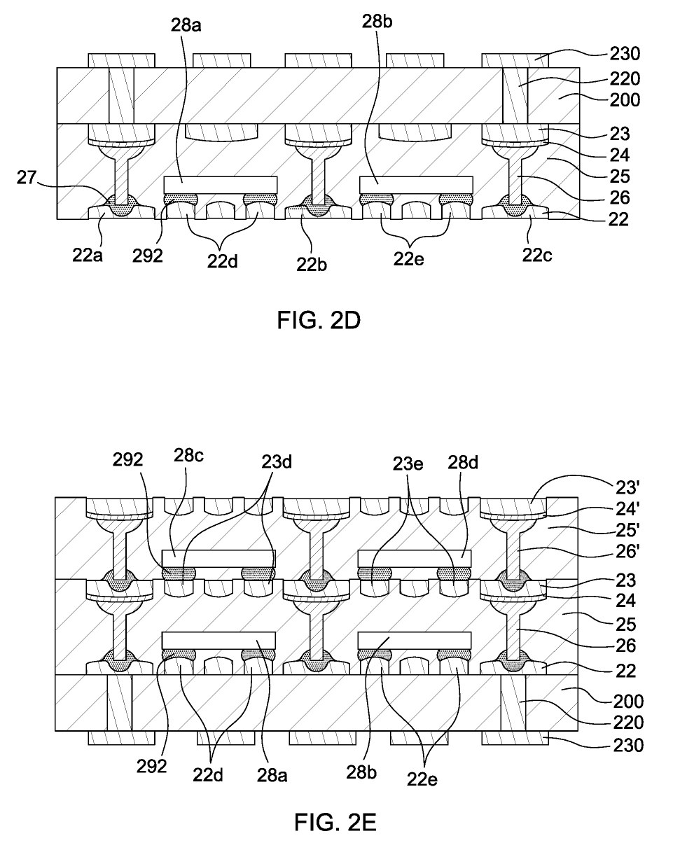

FIG. 2 is a schematic diagram illustrating a cross-sectional view of a semiconductor package structure according to some embodiments of the present disclosure. As shown in FIG. 2, the semiconductor package structure includes a patterned conductive layer 22, a patterned conductive layer 23, a metal finishing layer 24, an encapsulation layer 25, a stud bump 26, an electrical connection element 27, a substrate 200, a through via 220, and a patterned conductive layer 230. In some embodiments, the through via 220 includes a conductive post/pillar. In some embodiments, the through via 220 includes a laser via. In some embodiments, the through via 220 includes a Cu pillar. The substrate 200 may have several internal layers of conductors not shown for simplicity.

The patterned conductive layer 22 includes conductive pads 22a, 22b and 22c. The patterned conductive layer 22 may further include one or more traces disposed between the conductive pads. The patterned conductive layer 23 includes one or more conductive pads and one or more traces disposed between the conductive pads. The stud bump 26 includes a bump portion 26a and a stud portion 26b. The width of the bump portion 26a is greater than the width of the stud portion 26b (e.g. by a factor of about 1.2 or more, about 1.5 or more, or about 2.0 or more). The conductive pad 22a includes a portion 22a1 and a portion 22a2. In some embodiments, the portion 22a1 defines a recess, a dimple, or a cup shape. The conductive pads 22b and 22c are substantially in the same shape as the conductive pad 22a. The encapsulation layer 25 encapsulates the patterned conductive layer 22, the patterned conductive layer 23, the metal finishing layer 24, the stud bump 26 and the electrical connection element 27. The encapsulation layer 25 may include an epoxy, a filler, or other suitable materials.

The metal finishing layer 24 is disposed on the patterned conductive layer 23. The bump portion 26a is electrically connected to (and, for example, in contact with) the metal finishing layer 24, and the stud portion 26b is electrically connected to (and, for example, in contact with) the electrical connection element 27. In some embodiments, the metal finishing layer 24 may be omitted so that the bump portion 26a is electrically connected to (and, for example in contact with) a conductive pad of the patterned conductive layer 23. The electrical connection element 27 is disposed within the portion 22a1 (e.g. within the recess defined by the portion 22a1) and is electrically connected to (and, for example in contact with) the conductive pad 22a. Referring to FIG. 2, at least a portion of the patterned conductive layer 230 is electrically connected to the patterned conductive layer 22 through the through via 220. In some embodiments, the through via 220 includes a conductive post/pillar. In some embodiments, the through via 220 includes a laser via. In some embodiments, the through via 220 includes a Cu pillar. In some embodiments, the electrical connection elements 27 may include solder material, for example, tin (Sn), another metal or other suitable material. Although not shown in FIG. 2, in some embodiments, an intermetallic compound is formed between the electrical connection element 27 and the portion 22a1.

FIG. 2A is a schematic diagram illustrating a cross-sectional view of a semiconductor package structure according to some embodiments of the present disclosure. The semiconductor package structure shown in FIG. 2A is similar to the semiconductor package structure shown in FIG. 2, except that the conductive pad 22b does not define a recess portion, and that the stud bump 26 and the electrical connection element 27 above the conductive pad 22b are replaced by a die 28. The back surface of the die 28 is attached to the conductive pad 22b via an adhesive layer 29. The active surface of the die 28 is electrically connected to the patterned conductive layer 22 via a wire connection 210.

FIG. 2B is a schematic diagram illustrating a cross-sectional view of a semiconductor package structure according to some embodiments of the present disclosure. The semiconductor package structure shown in FIG. 2B is similar to the semiconductor package structure shown in FIG. 2, except that the conductive pad 22b is replaced by a plurality of conductive pads 22d and that a die 28 is mounted on the conductive pads 22d. As shown in FIG. 2B, the die 28 includes a plurality of connection pins 280. The plurality of connection pins 280 are electrically connected to the conductive pads 22d through electrical connection elements 290.

FIG. 2C is a schematic diagram illustrating a cross-sectional view of a semiconductor package structure according to some embodiments of the present disclosure. As shown in FIG. 2C, the semiconductor package structure includes a patterned conductive layer 22, a patterned conductive layer 23, a patterned conductive layer 23′, a metal finishing layer 24, a metal finishing layer 24′, an encapsulation layer 25, an encapsulation layer 25′, a stud bump 26, a stud bump 26′, an electrical connection element 27, an electrical connection element 27′, a substrate 200, a through via 220, and a patterned conductive layer 230. In some embodiments, the through via 220 includes a conductive post/pillar. In some embodiments, the through via 220 includes a laser via. In some embodiments, the through via 220 includes a Cu pillar.

The patterned conductive layer 22 includes conductive pads 22a, 22b and 22c. The patterned conductive layer 22 may further include one or more traces disposed between the conductive pads. The patterned conductive layer 23 includes conductive pads 23a, 23b and 23c. The patterned conductive layer 23 further includes one or more traces disposed between the conductive pads. The patterned conductive layer 23′ includes one or more conductive pads and one or more traces disposed between the conductive pads.

The conductive pads 22a, 22b, 22c 23a, 23b and 23c are in the same shape as the conductive pads 12a, 12b and 12c shown in FIG. 1. The stud bump 26 includes a bump portion 26a and a stud portion 26b. The width of the bump portion 26a is greater than the width of the stud portion 26b (e.g. by a factor of about 1.2 or more, about 1.5 or more, or about 2.0 or more). The stud bump 26′ includes a bump portion 26a′ and a stud portion 26b′. The width of the bump portion 26a′ is greater than the width of the stud portion 26b′ (e.g. by a factor of about 1.2 or more, about 1.5 or more, or about 2.0 or more).

The encapsulation layer 25 encapsulates the patterned conductive layer 22, the patterned conductive layer 23, the metal finishing layer 24, the stud bump 26 and the electrical connection element 27. The encapsulation layer 25′ encapsulates the patterned conductive layer 23′, the metal finishing layer 24′, the stud bump 26′ and the electrical connection element 27′. The encapsulation layer 25′ may include an epoxy, a filler, or other suitable materials. The metal finishing layer 24 is disposed on the patterned conductive layer 23 and the metal finishing layer 24′ is disposed on the patterned conductive layer 23′. The bump portion 26a is electrically connected to (and, for example in contact with) the metal finishing layer 24, and the stud portion 26b is electrically connected to (and, for example in contact with) the electrical connection element 27. In some embodiments, the metal finishing layer 24 may be omitted so that the bump portion 26a is electrically connected to (and, for example in contact with) a conductive pad 23a. The bump portion 26a′ is electrically connected to the metal finishing layer 24′, and the stud portion 26b′ is electrically connected to (and, for example in contact with) the electrical connection element 27′. In some embodiments, the metal finishing layer 24′ may be omitted so that the bump portion 26a′ is electrically connected to (and, for example in contact with) a conductive pad of the patterned conductive layer 23′. The electrical connection element 27 is disposed within the portion 22a1 (e.g. within the recess defined by the portion 22a1) and is electrically connected to the conductive pad 22a. The electrical connection element 27′ is disposed within the portion 23a1 (e.g. within the recess defined by the portion 23a1) and is electrically connected to (and, for example in contact with) the conductive pad 23a. In some embodiments, the electrical connection elements 27 and 27′ may include solder material, for example, tin (Sn), another metal or other suitable material.

Although not shown in FIG. 2C, in some embodiments, an intermetallic compound is formed between the electrical connection element 27 and the portion 22a1, and an intermetallic compound is formed between the electrical connection element 27′ and the portion 23a1. Referring to FIG. 2C, at least a portion of the patterned conductive layer 230 is electrically connected to the patterned conductive layer 22 through the through via 220. In some embodiments, the through via 220 includes a conductive post/pillar. In some embodiments, the through via 220 includes a laser via. In some embodiments, the through via 220 includes a copper (Cu) pillar.

FIG. 2D is a schematic diagram illustrating a cross-sectional view of a semiconductor package structure according to some embodiments of the present disclosure. As shown in FIG. 2D, the semiconductor package structure includes a patterned conductive layer 22, a patterned conductive layer 23, a metal finishing layer 24, an encapsulation layer 25, a stud bump 26, an electrical connection element 27, dies 28a and 28b, a substrate 200, a through via 220, and a patterned conductive layer 230. In some embodiments, the through via 220 includes a conductive post/pillar. In some embodiments, the through via 220 includes a laser via. In some embodiments, the through via 220 includes a Cu pillar.

The patterned conductive layer 22 includes conductive pads 22a, 22b, 22c, 22d and 22e. The patterned conductive layer 22 may further include one or more traces disposed between the conductive pads. The stud bump 26 includes a bump portion 26a and a stud portion 26b. The width of the bump portion 26a is greater than the width of the stud portion 26b (e.g. by a factor of about 1.2 or more, about 1.5 or more, or about 2.0 or more). The conductive pad 22a includes a portion 22a1 and a portion 22a2. In some embodiments, the portion 22a1 defines a recess, a dimple, or a cup shape. The conductive pads 22b and 22c are substantially in the same shape as the conductive pad 22a. Dies 28a and 28b are respectively electrically connected to conductive pads 22d and 22e through electrical connection elements 292. As shown in FIG. 2D, the encapsulation layer 25 encapsulates the patterned conductive layer 22, the patterned conductive layer 23, the metal finishing layer 24, the stud bump 26, the electrical connection element 27 and the dies 28a and 28b.

The metal finishing layer 24 is disposed on the patterned conductive layer 23. The bump portion 26a is electrically connected to (and, for example, in contact with) the metal finishing layer 24, and the stud portion 26b is electrically connected to (and, for example, in contact with) the electrical connection element 27. In some embodiments, the metal finishing layer 24 may be omitted so that the bump portion 26a is electrically connected to (and, for example, in contact with) a conductive pad of the patterned conductive layer 23. The electrical connection element 27 is disposed within the portion 22a1 (e.g. within the recess defined by the portion 22a1) and is electrically connected to (and, for example, in contact with) the conductive pad 22a. Referring to FIG. 2D, at least a portion of the patterned conductive layer 230 is electrically connected to the patterned conductive layer 23 through the through via 220. In some embodiments, the through via 220 includes a conductive post/pillar. In some embodiments, the through via 220 includes a laser via. In some embodiments, the through via 220 includes a Cu pillar. Although not shown in FIG. 2D, in some embodiments, an intermetallic compound is formed between the electrical connection element 27 and the portion 22a1.

FIG. 2E is a schematic diagram illustrating a cross-sectional view of a semiconductor package structure according to some embodiments of the present disclosure. The semiconductor package structure shown in FIG. 2E is similar to the semiconductor package structure shown in FIG. 2C, except that the semiconductor package structure shown in FIG. 2E further includes dies 28a, 28b, 28c and 28d. The dies 28a and 28b are respectively electrically connected to conductive pads 22d and 22e through electrical connection elements 292. The dies 28c and 28d are respectively electrically connected to conductive pads 23d and 23e through electrical connection elements 292.

As shown in FIG. 2E, the encapsulation layer 25 encapsulates the patterned conductive layer 22, the patterned conductive layer 23, the metal finishing layer 24, the stud bump 26, the electrical connection element 27 and the dies 28a and 28b. The encapsulation layer 25′ encapsulates the patterned conductive layer 23′, the metal finishing layer 24′, the stud bump 26′, the electrical connection element 27′ and the dies 28c and 28d.

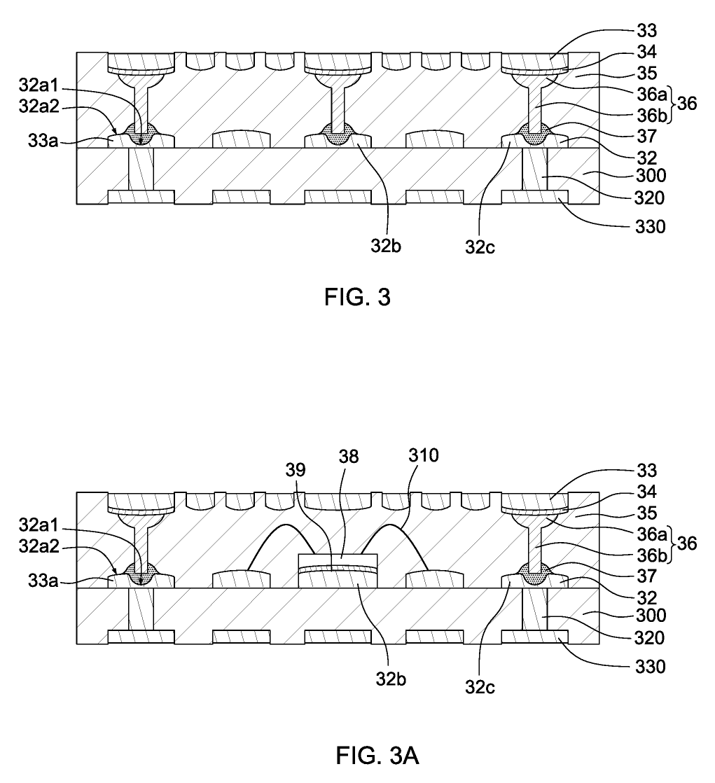

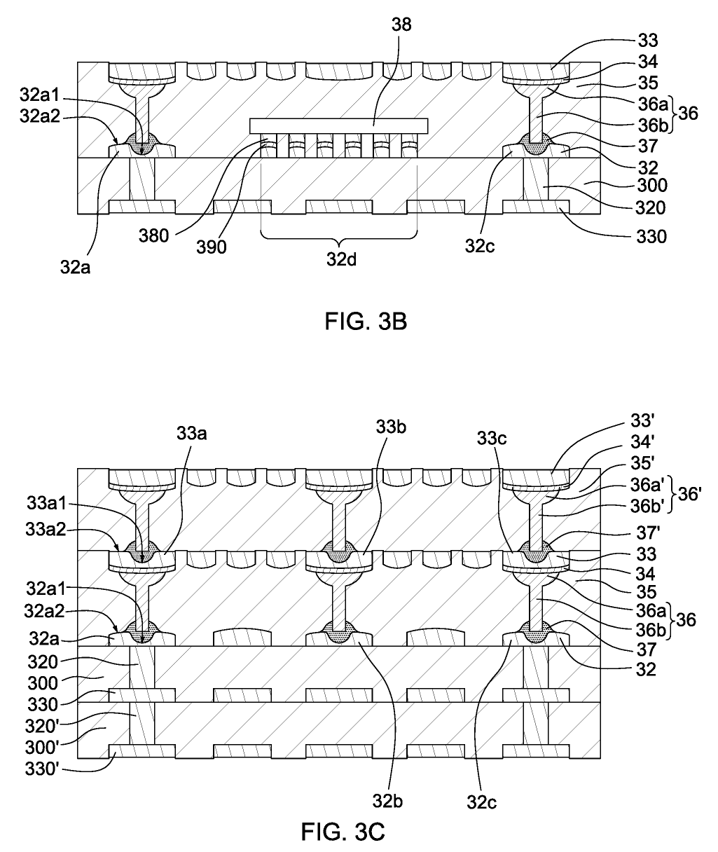

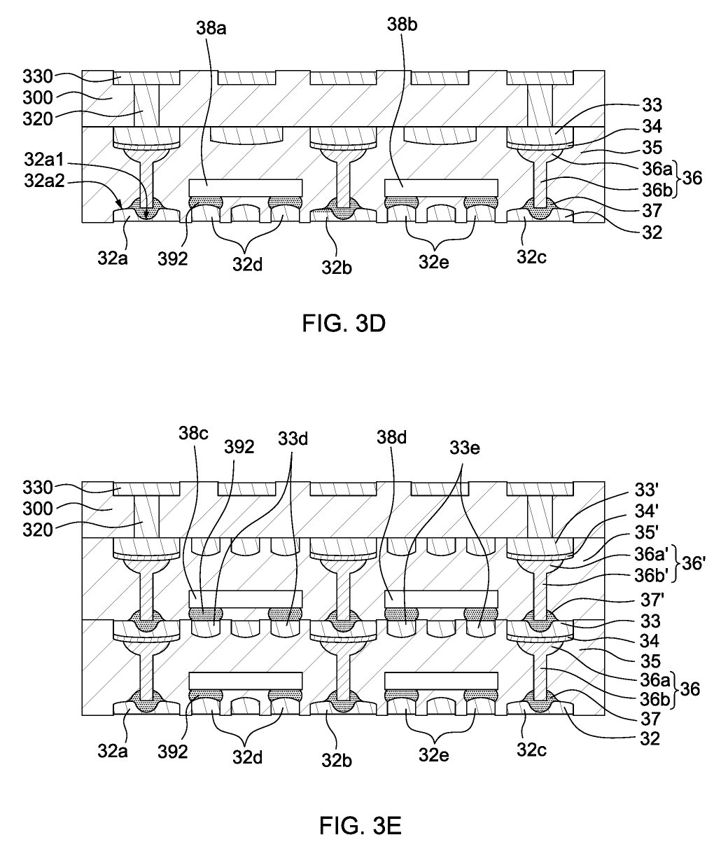

FIG. 3 is a schematic diagram illustrating a cross-sectional view of a semiconductor package structure according to some embodiments of the present disclosure. As shown in FIG. 3, the semiconductor package structure includes a patterned conductive layer 32, a patterned conductive layer 33, a metal finishing layer 34, an encapsulation layer 35, a stud bump 36, an electrical connection element 37, a substrate 300, a through via 320, and a patterned conductive layer 330 embedded in the substrate 300. In some embodiments, the through via 320 includes a conductive post/pillar. In some embodiments, the through via 320 includes a laser via. In some embodiments, the through via 320 includes a Cu pillar.

The patterned conductive layer 32 includes conductive pads 32a, 32b and 32c. The patterned conductive layer 32 may further include one or more traces disposed between the conductive pads. The patterned conductive layer 33 includes one or more conductive pads and one or more traces disposed between the conductive pads. The stud bump 36 includes a bump portion 36a and a stud portion 36b. The width of the bump portion 36a is greater than the width of the stud portion 36b (e.g. by a factor of about 1.2 or more, about 1.5 or more, or about 2.0 or more). The conductive pad 32a includes a portion 32a1 and a portion 32a2. In some embodiments, the portion 32a1 defines a recess, a dimple, or a cup shape. The conductive pads 32b and 32c are substantially in the same shape as the conductive pad 32a. The encapsulation layer 35 encapsulates the patterned conductive layer 32, the patterned conductive layer 33, the metal finishing layer 34, the stud bump 36 and the electrical connection element 37. The encapsulation layer 35 may include an epoxy, a filler, or other suitable materials.

The metal finishing layer 34 is disposed on the patterned conductive layer 33. The bump portion 36a is electrically connected to (and, for example, in contact with) the metal finishing layer 34, and the stud portion 36b is electrically connected to (and, for example, in contact with) the electrical connection element 37. In some embodiments, the metal finishing layer 34 may be omitted so that the bump portion 36a is electrically connected to (and, for example, in contact with) a conductive pad of the patterned conductive layer 33. The electrical connection element 37 is disposed within the portion 32a1 (e.g. within the recess defined by the portion 32a1) and is electrically connected to (and, for example, in contact with) the conductive pad 32a. In some embodiments, the electrical connection elements 37 may include solder material, for example, tin (Sn), another metal or other suitable material.

Referring to FIG. 3, at least a portion of the patterned conductive layer 330 is electrically connected to the patterned conductive layer 32 through the through via 320. In some embodiments, the through via 320 includes a conductive post/pillar. In some embodiments, the through via 320 includes a laser via. In some embodiments, the through via 320 includes a Cu pillar. Although not shown in FIG. 3, in some embodiments, an intermetallic compound is formed between the electrical connection element 37 and the portion 32a1.

FIG. 3A is a schematic diagram illustrating a cross-sectional view of a semiconductor package structure according to some embodiments of the present disclosure. The semiconductor package structure shown in FIG. 3A is similar to the semiconductor package structure shown in FIG. 3, except that the conductive pad 32b does not define a recess portion, and that the stud bump 36 and the electrical connection element 37 above the conductive pad 32b are replaced by a die 38. The back surface of the die 38 is attached to the conductive pad 32b via an adhesive layer 39. The active surface of the die 38 is electrically connected to the patterned conductive layer 32 via a wire connection 310.

FIG. 3B is a schematic diagram illustrating a cross-sectional view of a semiconductor package structure according to some embodiments of the present disclosure. The semiconductor package structure shown in FIG. 3B is similar to the semiconductor package structure shown in FIG. 3, except that the conductive pad 32b is replaced by a plurality of conductive pads 32d and that a die 38 is mounted on the conductive pads 32d. As shown in FIG. 3B, the die 38 includes a plurality of connection pins 380. The plurality of connection pins 380 are electrically connected to the conductive pads 32d through electrical connection elements 390.

FIG. 3C is a schematic diagram illustrating a cross-sectional view of a semiconductor package structure according to some embodiments of the present disclosure. As shown in FIG. 3C, the semiconductor package structure includes a patterned conductive layer 32, a patterned conductive layer 33, a patterned conductive layer 33′, a metal finishing layer 34, a metal finishing layer 34′, an encapsulation layer 35, an encapsulation layer 35′, a stud bump 36, a stud bump 36′, an electrical connection element 37, an electrical connection element 37′, a substrate 300, a substrate 300′, a through via 320, a through via 320′, a patterned conductive layer 330 embedded in the substrate 300 and a patterned conductive layer 330′ embedded in the substrate 300′. In some embodiments, the through via 320 includes a conductive post/pillar. In some embodiments, the through via 320 includes a laser via. In some embodiments, the through via 320 includes a Cu pillar. In some embodiments, the through via 320′ includes a conductive post/pillar. In some embodiments, the through via 320′ includes a laser via. In some embodiments, the through via 320′ includes a Cu pillar.

The patterned conductive layer 32 includes conductive pads 32a, 32b and 32c. The patterned conductive layer 32 may further include one or more traces disposed between the conductive pads. The patterned conductive layer 33 includes conductive pads 33a, 33b and 33c. The patterned conductive layer 33 may further include one or more traces disposed between the conductive pads. The patterned conductive layer 33′ includes one or more conductive pads and one or more traces disposed between the conductive pads. The conductive pads 32a, 32b and 32c are in the same shape as those shown in FIG. 3. The conductive pads 33a, 33b and 33c are substantially in the same shape as conductive pads 32a, 32b and 32c. The stud bump 36 includes a bump portion 36a and a stud portion 36b. The width of the bump portion 36a is greater than the width of the stud portion 36b (e.g. by a factor of about 1.2 or more, about 1.5 or more, or about 2.0 or more). The stud bump 36′ includes a bump portion 36a′ and a stud portion 36b′. The width of the bump portion 36a′ is greater than the width of the stud portion 36b′ (e.g. by a factor of about 1.2 or more, about 1.5 or more, or about 2.0 or more).

The encapsulation layer 35 encapsulates the patterned conductive layer 32, the patterned conductive layer 33, the metal finishing layer 34, the stud bump 36 and the electrical connection element 37. The encapsulation layer 35′ encapsulates the patterned conductive layer 33′, the metal finishing layer 34′, the stud bump 36′ and the electrical connection element 37′. The encapsulation layer 35′ may include an epoxy, a filler, or other suitable materials.

The metal finishing layer 34 is disposed on the patterned conductive layer 33 and the metal finishing layer 34′ is disposed on the patterned conductive layer 33′. The bump portion 36a is electrically connected to (and, for example, in contact with) the metal finishing layer 34, and the stud portion 36b is electrically connected to (and, for example, in contact with) the electrical connection element 37. In some embodiments, the metal finishing layer 34 may be omitted so that the bump portion 36a is electrically connected to (and, for example, in contact with) a conductive pad of the patterned conductive layer 33. The bump portion 36a′ is electrically connected to (and, for example, in contact with) the metal finishing layer 34′, and the stud portion 36b′ is electrically connected to (and, for example, in contact with) the electrical connection element 37′. In some embodiments, the metal finishing layer 34′ may be omitted so that the bump portion 36a′ is electrically connected to (and, for example, in contact with) a conductive pad of the patterned conductive layer 33′. The electrical connection element 37 is disposed within the portion 32a1 (e.g. within the recess defined by the portion 32a1) and is electrically connected to (and, for example, in contact with) the conductive pad 32a. The electrical connection element 37′ is disposed within the portion 33a1 (e.g. within the recess defined by the portion 33a1) and is electrically connected to (and, for example, in contact with) the conductive pad 33a.

Referring to FIG. 3C, at least a portion of the patterned conductive layer 330 is electrically connected to the patterned conductive layer 330′ through the through via 320′, and at least a portion of the patterned conductive layer 330 is electrically connected to the patterned conductive layer 32 through the through via 320. Although not shown in FIG. 3C, in some embodiments, an intermetallic compound is formed between the electrical connection element 37 and the portion 32a1, and an intermetallic compound is formed between the electrical connection element 37′ and the portion 33a1. In some embodiments, the through via 320 includes a conductive post/pillar. In some embodiments, the through via 320 includes a laser via. In some embodiments, the through via 320 includes a Cu pillar.

FIG. 3D is a schematic diagram illustrating a cross-sectional view of a semiconductor package structure according to some embodiments of the present disclosure. As shown in FIG. 3D, the semiconductor package structure includes a patterned conductive layer 32, a patterned conductive layer 33, a metal finishing layer 34, an encapsulation layer 35, a stud bump 36, an electrical connection element 37, dies 38a and 38b, a substrate 300, a through via 320, and a patterned conductive layer 330 embedded in the substrate 300. In some embodiments, the through via 320 includes a conductive post/pillar. In some embodiments, the through via 320 includes a laser via. In some embodiments, the through via 320 includes a Cu pillar.

The patterned conductive layer 32 includes conductive pads 32a, 32b, 32c, 32d and 32e. The stud bump 36 includes a bump portion 36a and a stud portion 36b. The width of the bump portion 36a is greater than the width of the stud portion 36b (e.g. by a factor of about 1.2 or more, about 1.5 or more, or about 2.0 or more). The conductive pad 32a includes a portion 32a1 and a portion 32a2. The conductive pads 32b and 32c are substantially in the same shape as the conductive pad 32a. Dies 38a and 38b are respectively electrically connected to conductive pads 32d and 32e through electrical connection elements 392. As shown in FIG. 3D, the encapsulation layer 35 encapsulates the patterned conductive layer 32, the patterned conductive layer 33, the metal finishing layer 34, the stud bump 36, the electrical connection element 37 and the dies 38a and 38b.

The metal finishing layer 34 is disposed on the patterned conductive layer 33. The bump portion 36a is electrically connected to (and, for example, in contact with) the metal finishing layer 34, and the stud portion 36b is electrically connected to (and, for example, in contact with) the electrical connection element 37. In some embodiments, the metal finishing layer 34 may be omitted so that the bump portion 36a is electrically connected to (and, for example, in contact with) a conductive pad of the patterned conductive layer 33. The electrical connection element 37 is disposed within the portion 32a1 (e.g. within the recess defined by the portion 32a1) and is electrically connected to (and, for example, in contact with) the conductive pad 32a. Referring to FIG. 3D, at least a portion of the patterned conductive layer 330 is electrically connected to the patterned conductive layer 33 through the through via 320. Although not shown in FIG. 3D, in some embodiments, an intermetallic compound is formed between the electrical connection element 37 and the portion 32a1.

FIG. 3E is a schematic diagram illustrating a cross-sectional view of a semiconductor package structure according to some embodiments of the present disclosure. As shown in FIG. 3E, the semiconductor package structure includes a patterned conductive layer 32, a patterned conductive layer 33, a patterned conductive layer 33′, a metal finishing layer 34, a metal finishing layer 34′, an encapsulation layer 35, an encapsulation layer 35′, a stud bump 36, a stud bump 36′, an electrical connection element 37, an electrical connection element 37′, dies 38a, 38b, 38c and 38d, a substrate 300, a through via 320, and a patterned conductive layer 330 embedded in the substrate 300. In some embodiments, the through via 320 includes a conductive post/pillar. In some embodiments, the through via 320 includes a laser via. In some embodiments, the through via 320 includes a Cu pillar.

The patterned conductive layer 32 includes conductive pads 32a, 32b, 32c, 32d and 32e. The patterned conductive layer 32 may further include one or more traces disposed between the conductive pads. The patterned conductive layer 33 includes conductive pads 33a, 33b, 33c, 33d and 33e. The patterned conductive layer 33 may further include one or more traces disposed between the conductive pads. The stud bump 36 includes a bump portion 36a and a stud portion 36b. The width of the bump portion 36a is greater than the width of the stud portion 36b (e.g. by a factor of about 1.2 or more, about 1.5 or more, or about 2.0 or more). The stud bump 36′ includes a bump portion 36a′ and a stud portion 36b′. The width of the bump portion 36a′ is greater than the width of the stud portion 36b′ (e.g. by a factor of about 1.2 or more, about 1.5 or more, or about 2.0 or more). The conductive pad 32a includes a portion 32a1 and a portion 32a2. In some embodiments, the portion 32a2 defines a recess, a dimple, or a cup shape. The conductive pads 32b, 32c, 33a, 33b and 33c are substantially in the same shape as the conductive pad 32a. Dies 38a, 38b, 38c and 38d are respectively electrically connected to conductive pads 32d, 32e, 33d and 33e through electrical connection elements 392.

As shown in FIG. 3E, the encapsulation layer 35 encapsulates the patterned conductive layer 32, the patterned conductive layer 33, the metal finishing layer 34, the stud bump 36, the electrical connection element 37 and the dies 38a and 38b. The encapsulation layer 35′ encapsulates the patterned conductive layer 33′, the metal finishing layer 34′, the stud bump 36′, the electrical connection element 37′ and the dies 38c and 38d.

The metal finishing layer 34 is disposed on the patterned conductive layer 33. The bump portion 36a is electrically connected to (and, for example, in contact with) the metal finishing layer 34, and the stud portion 36b is electrically connected to (and, for example, in contact with) the electrical connection element 37. In some embodiments, the metal finishing layer 34 may be omitted so that the bump portion 36a is electrically connected to (and, for example, in contact with) a conductive pad of the patterned conductive layer 33. The electrical connection element 37 is disposed within the portion 32a1 (e.g. within the recess defined by the portion 32a1) and is electrically connected to (and, for example, in contact with) the conductive pad 32a. The metal finishing layer 34′ is disposed on the patterned conductive layer 33′. The bump portion 36a′ is electrically connected to (and, for example, in contact with) the metal finishing layer 34′, and the stud portion 36b′ is electrically connected to (and, for example, in contact with) the electrical connection element 37′. In some embodiments, the metal finishing layer 34′ may be omitted so that the bump portion 36a′ is electrically connected to (and, for example, in contact with) a conductive pad of the patterned conductive layer 33′. The electrical connection element 37′ is disposed within the portion 33a1 (e.g. within the recess defined by the portion 33a1) and is electrically connected to (and, for example, in contact with) the conductive pad 33a.

Referring to FIG. 3E, at least a portion of the patterned conductive layer 330 is electrically connected to the patterned conductive layer 33′ through the through via 320. Although not shown in FIG. 3E, in some embodiments, an intermetallic compound is formed between the electrical connection element 37 and the portion 32a1. In some embodiments, an intermetallic compound is formed between the electrical connection element 37′ and the portion 33a1. In some embodiments, the through via 320 includes a conductive post/pillar. In some embodiments, the through via 320 includes a laser via. In some embodiments, the through via 320 includes a Cu pillar.

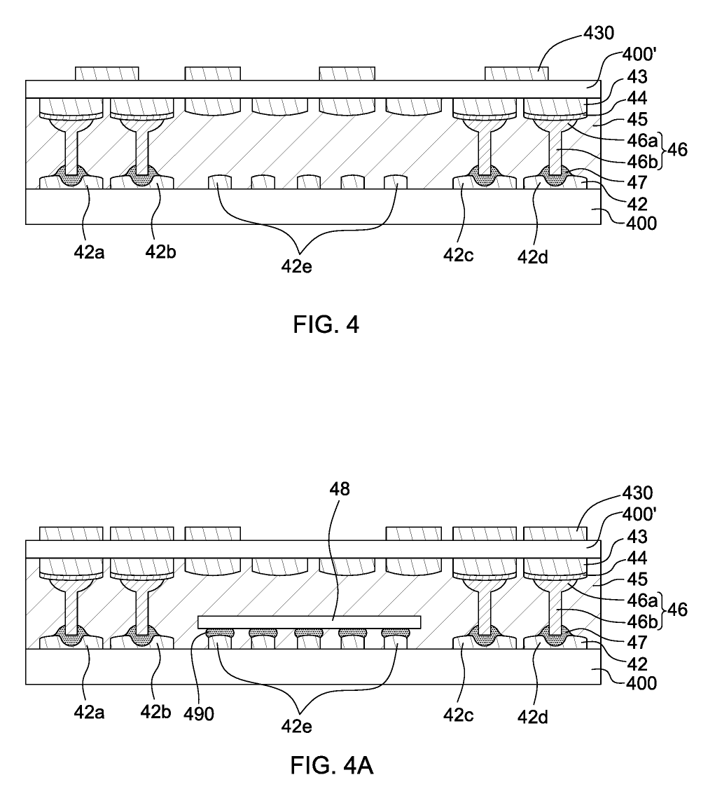

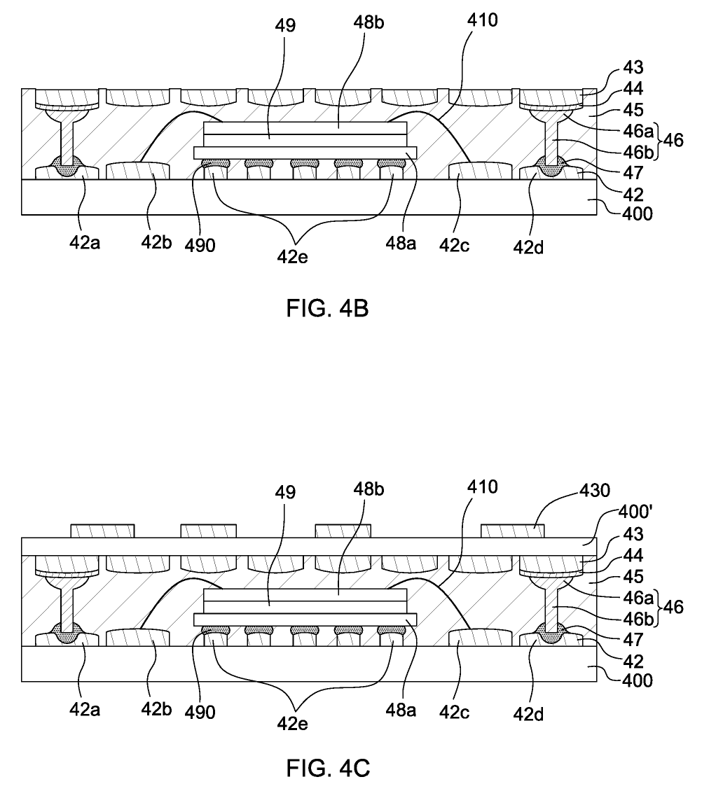

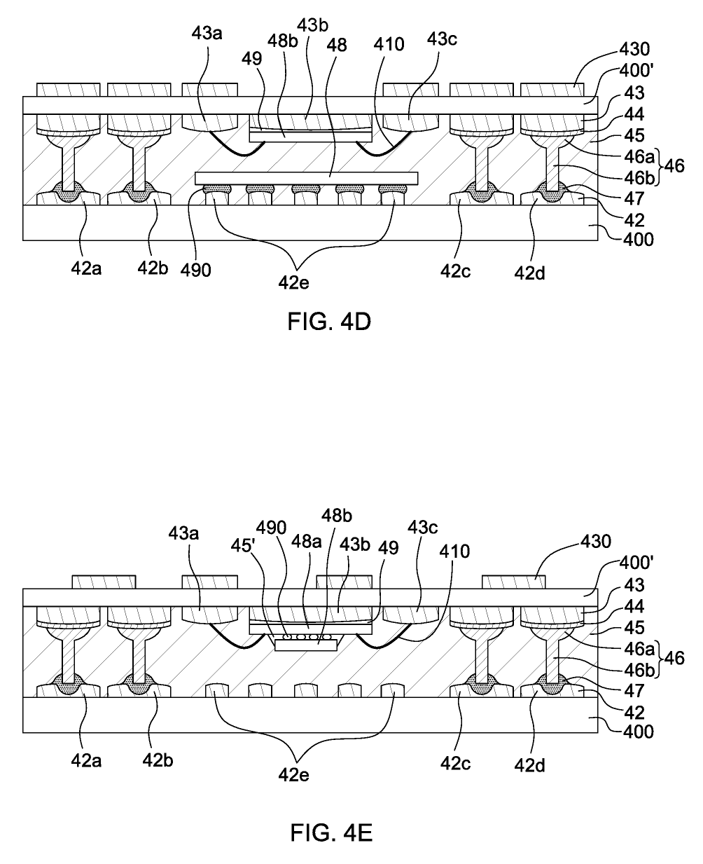

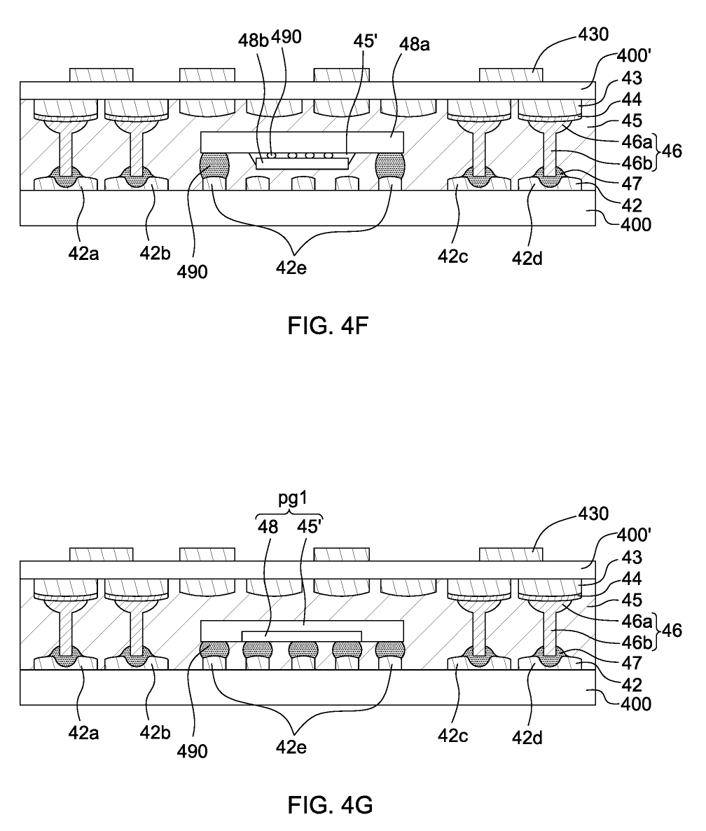

FIG. 4 is a schematic diagram illustrating a cross-sectional view of a semiconductor package structure according to some embodiments of the present disclosure. As shown in FIG. 4, the semiconductor package structure includes a patterned conductive layer 42, a patterned conductive layer 43, a metal finishing layer 44, an encapsulation layer 45, a stud bump 46, an electrical connection element 47, a substrate 400, a substrate 400′, and a patterned conductive layer 430 disposed on the substrate 400′.

The patterned conductive layer 42 includes conductive pads 42a, 42b, 42c, 42d and 42e. Although not shown in FIG. 4, in some embodiments, the patterned conductive layer 42 may further include one or more traces disposed between the conductive pads. The patterned conductive layer 43 includes one or more conductive pads and one or more traces disposed between the conductive pads. The stud bump 46 includes a bump portion 46a and a stud portion 46b. The width of the bump portion 46a is greater than the width of the stud portion 46b (e.g. by a factor of about 1.2 or more, about 1.5 or more, or about 2.0 or more). The conductive pad 42a includes a portion 42a1 and a portion 42a2. The portion 42a1 may define a recess, a dimple, or a cup shape. The conductive pads 42b, 42c and 42d are substantially in the same shape as the conductive pad 42a. The encapsulation layer 45 encapsulates the patterned conductive layer 42, the patterned conductive layer 43, the metal finishing layer 44, the stud bump 46 and the electrical connection element 47. The encapsulation layer 45 may include an epoxy, a filler, or other suitable materials.

The metal finishing layer 44 is disposed on the patterned conductive layer 43. The bump portion 46a is electrically connected to (and, for example, in contact with) the metal finishing layer 44, and the stud portion 46b is electrically connected to (and, for example, in contact with) the electrical connection element 47. In some embodiments, the metal finishing layer 44 may be omitted so that the bump portion 46a is electrically connected to (and, for example, in contact with) a conductive pad of the patterned conductive layer 43. The electrical connection element 47 is disposed within the portion 42a1 (e.g. within the recess defined by the portion 42a1) and is electrically connected to (and, for example, in contact with) the conductive pad 42a. In some embodiments, the electrical connection elements 47 may include solder material, for example, tin (Sn), another metal or other suitable material. Although not shown in FIG. 4, in some embodiments, an intermetallic compound is formed between the electrical connection element 47 and the portion 42a1.

FIG. 4A is a schematic diagram illustrating a cross-sectional view of a semiconductor package structure according to some embodiments of the present disclosure. The semiconductor package structure shown in FIG. 4A is similar to the semiconductor package structure shown in FIG. 4, except that the semiconductor package structure shown in FIG. 4A further includes a die 48 mounted on the conductive pads 42e. As shown in FIG. 4A, the die 48 is electrically connected to the conductive pads 42e through electrical connection elements 490.

FIG. 4B is a schematic diagram illustrating a cross-sectional view of a semiconductor package structure according to some embodiments of the present disclosure. As shown in FIG. 4B, the semiconductor package structure includes a patterned conductive layer 42, a patterned conductive layer 43, a metal finishing layer 44, an encapsulation layer 45, a stud bump 46, an electrical connection element 47, dies 48a and 48b and a substrate 400.

The patterned conductive layer 42 includes conductive pads 42a, 42b, 42c, 42d and 42e. The stud bump 46 includes a bump portion 46a and a stud portion 46b. The width of the bump portion 46a is greater than the width of the stud portion 46b (e.g. by a factor of about 1.2 or more, about 1.5 or more, or about 2.0 or more). The conductive pad 42a includes a portion 42a1 and a portion 42a2. In some embodiments, the portion 42a1 defines a recess, a dimple, or a cup shape. The conductive pad 42b is substantially in the same shape as the conductive pad 42a. The conductive pads 42b, 42c and 42e do not define a recess portion. The encapsulation layer 45 encapsulates the patterned conductive layer 42, the patterned conductive layer 43, the metal finishing layer 44, the stud bump 46, the electrical connection element 47 and dies 48a and 48b.

The metal finishing layer 44 is disposed on the patterned conductive layer 43. The bump portion 46a is electrically connected to (and, for example, in contact with) the metal finishing layer 44, and the stud portion 46b is electrically connected to (and, for example, in contact with) the electrical connection element 47. In some embodiments, the metal finishing layer 44 may be omitted so that the bump portion 46a is electrically connected to (and, for example, in contact with) a conductive pad of the patterned conductive layer 43. The electrical connection element 47 is disposed within the portion 42a1 (e.g. within the recess defined by the portion 42a1) and is electrically connected to (and, for example, in contact with) the conductive pad 42a. Although not shown in FIG. 4B, in some embodiments, an intermetallic compound is formed between the electrical connection element 47 and the portion 42a1. The die 48a is electrically connected to the conductive pads 42e through electrical connection elements 490. The back surface of the die 48b is attached to the back surface of the die 48a via an adhesive layer 49. The active surface of the die 48b is electrically connected to the conductive pads 42b and 42c via wire connections 410.

FIG. 4C is a schematic diagram illustrating a cross-sectional view of a semiconductor package structure according to some embodiments of the present disclosure. The semiconductor package structure shown in FIG. 4C is similar to the semiconductor package structure shown in FIG. 4B, except that the semiconductor package structure shown in FIG. 4C further includes a substrate 400′ and a patterned conductive layer 430 disposed on the substrate 400′.

FIG. 4D is a schematic diagram illustrating a cross-sectional view of a semiconductor package structure according to some embodiments of the present disclosure. The semiconductor package structure shown in FIG. 4D is similar to the semiconductor package structure shown in FIG. 4A, except that the semiconductor package structure shown in FIG. 4D further includes a die 48b attached to the conductive pad 43b through an adhesive layer 49, and that the active surface of the die 48b is electrically connected to the conductive pads 43a and 43c via wire connections 410.

FIG. 4E is a schematic diagram illustrating a cross-sectional view of a semiconductor package structure according to some embodiments of the present disclosure. The semiconductor package structure shown in FIG. 4E is similar to the semiconductor package structure shown in FIG. 4, except that the semiconductor package structure shown in FIG. 4E further includes a die 48a and a die 48b. The die 48b is electrically connected to the die 48a through electrical connection elements 490. Underfill 45′ is filled in the space between the die 48a and the die 48b. In some embodiments, the underfill 45′ may include an epoxy, a resin, a filler, or other suitable materials. In some embodiments, the underfill 45′ may include a protection layer. The die 48a is attached to the conductive pad 43b through an adhesive layer 49, and the active surface of the die 48a is electrically connected to the conductive pads 43a and 43c via wire connections 410.

FIG. 4F is a schematic diagram illustrating a cross-sectional view of a semiconductor package structure according to some embodiments of the present disclosure. The semiconductor package structure shown in FIG. 4F is similar to the semiconductor package structure shown in FIG. 4, except that the semiconductor package structure shown in FIG. 4F further includes a die 48a and a die 48b. The die 48b is electrically connected to the die 48a through electrical connection elements 490. Underfill 45′ is filled in the space between the die 48a and the die 48b. In some embodiments, the underfill 45′ may include an epoxy, a resin, a filler, or other suitable materials. In some embodiments, the underfill 45′ may include a protection layer. The die 48a is electrically connected to some of the conductive pads 42e through electrical connection elements 490.

FIG. 4G is a schematic diagram illustrating a cross-sectional view of a semiconductor package structure according to some embodiments of the present disclosure. The semiconductor package structure shown in FIG. 4G is similar to the semiconductor package structure shown in FIG. 4, except that the semiconductor package structure shown in FIG. 4G further includes a semiconductor package pg1. The semiconductor package pg1 includes a die 48 and an encapsulation body 45′. The encapsulation body 45′ encapsulates the die 48. The encapsulation body 45′ may be formed of an epoxy, a filler, or other suitable materials. The semiconductor package pg1 is electrically connected to the conductive pads 42e through electrical connection elements 490.

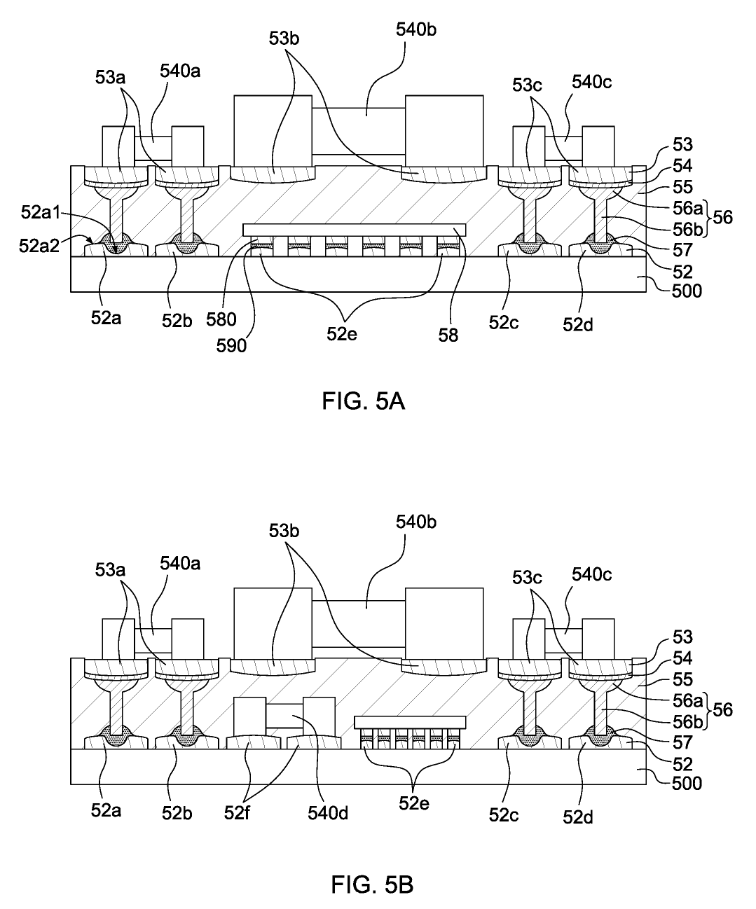

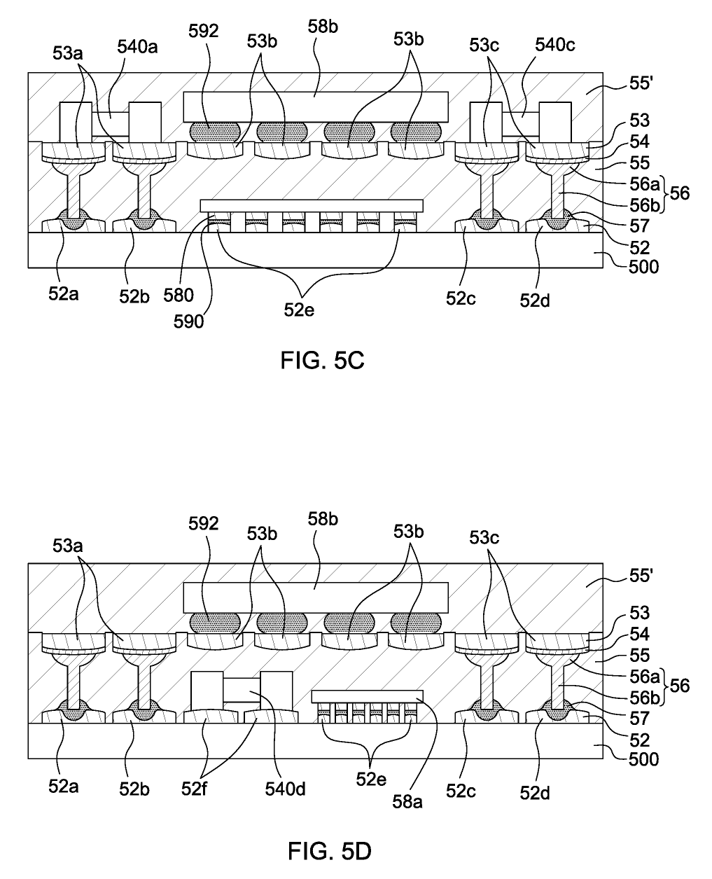

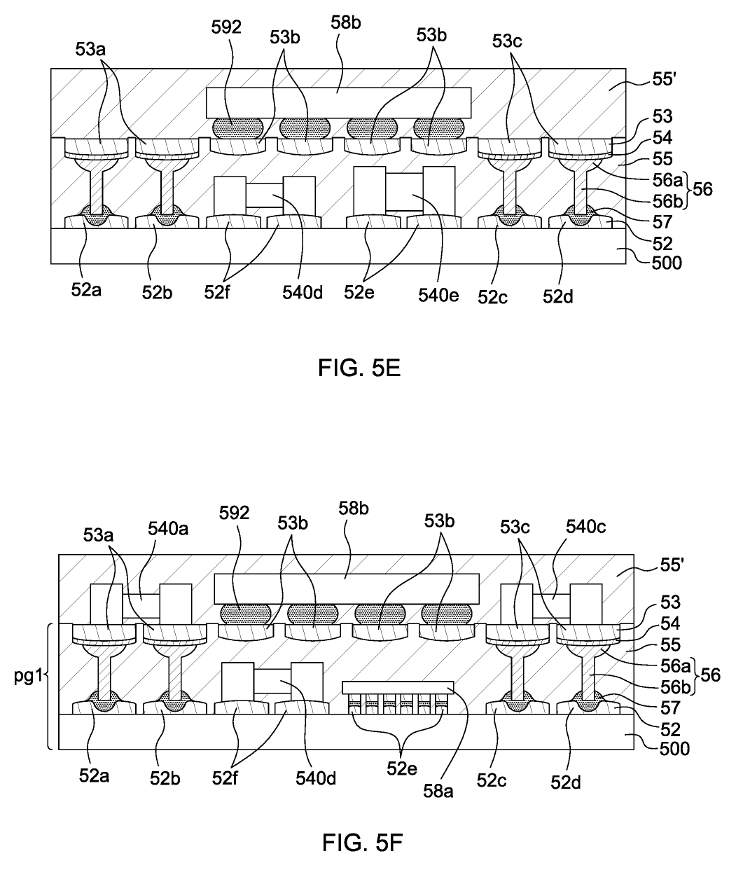

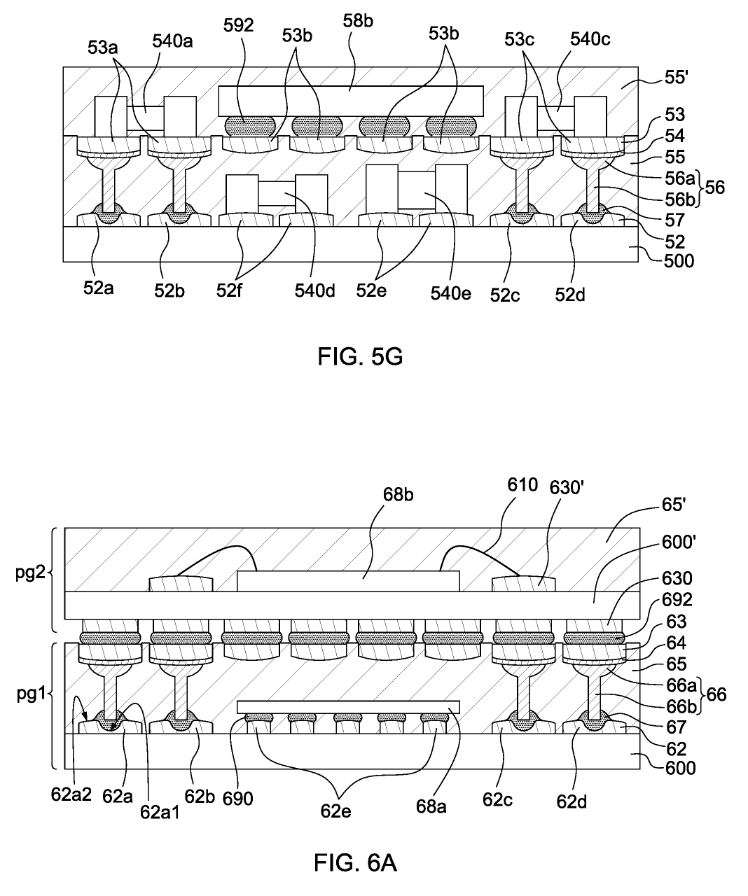

FIG. 5A is a schematic diagram illustrating a cross-sectional view of a semiconductor package structure according to some embodiments of the present disclosure. As shown in FIG. 5A, the semiconductor package structure includes a patterned conductive layer 52, a patterned conductive layer 53, a metal finishing layer 54, an encapsulation layer 55, a stud bump 56, an electrical connection element 57, a die 58, electrical components 540a, 540b and 540c, and a substrate 500.

The patterned conductive layer 52 includes conductive pads 52a, 52b, 52c, 52d and 52e. Although not shown in FIG. 5A, the patterned conductive layer 52 may include one or more traces between any two of the conductive pads 52a, 52b, 52c, 52d and 52e. The patterned conductive layer 53 includes conductive pads 53a, 53b and 53c. Although not shown in FIG. 5A, the patterned conductive layer 53 may include one or more traces between any two of the conductive pads 53a, 53b and 53c.

The stud bump 56 includes a bump portion 56a and a stud portion 56b. The width of the bump portion 56a is greater than the width of the stud portion 56b (e.g. by a factor of about 1.2 or more, about 1.5 or more, or about 2.0 or more). The conductive pad 52a includes a portion 52a1 and a portion 52a2. The portion 52a2 may define a recess, dimple, or cup shape. The conductive pads 52b, 52c and 52d are substantially in the same shape as the conductive pad 52a. The encapsulation layer 55 encapsulates the patterned conductive layer 52, the patterned conductive layer 53, the metal finishing layer 54, the stud bump 56, the electrical connection element 57 and the die 58. The encapsulation layer 55 may include an epoxy, a filler, or other suitable materials.

The metal finishing layer 54 is disposed on the patterned conductive layer 53. The bump portion 56a is electrically connected to (and, for example, in contact with) the metal finishing layer 54, and the stud portion 56b is electrically connected to (and, for example, in contact with) the electrical connection element 57. In some embodiments, the metal finishing layer 54 may be omitted so that the bump portion 56a is electrically connected to (and, for example, in contact with) a conductive pad of the patterned conductive layer 53. The electrical connection element 57 is disposed within the portion 52a1 (e.g. within the recess defined by the portion 52a1) and is electrically connected to (and, for example, in contact with) the conductive pad 52a. In some embodiments, the electrical connection elements 57 may include solder material, for example, tin (Sn), another metal or other suitable material. Although not shown in FIG. 5A, in some embodiments, an intermetallic compound is formed between the electrical connection element 57 and the portion 52a1.

As shown in FIG. 5A, the die 58 includes a plurality of connection pins 580. The plurality of connection pins 580 are electrically connected to the conductive pads 52e through electrical connection elements 590. The electrical component 540a is electrically connected to the conductive pads 53a, the electrical component 540b is electrically connected to the conductive pads 53b, and the electrical component 540c is electrically connected to the conductive pads 53c.

Although not shown in FIG. 5A, electrical connection elements may be disposed between the electrical component 540a and the conductive pads 53a, electrical connection elements may be disposed between the electrical component 540b and the conductive pads 53b, and electrical connection elements may be disposed between the electrical component 540c and the conductive pads 53c. In some embodiments, the electrical components 540a, 540b and 540c can include, but are not limited to, any of resistors, capacitors, inductors, transistors, tunnel diodes, metamaterial components, dissipative components or energy-neutral components.

FIG. 5B is a schematic diagram illustrating a cross-sectional view of a semiconductor package structure according to some embodiments of the present disclosure. The semiconductor package structure shown in FIG. 5B is similar to the semiconductor package structure shown in FIG. 5A, except that the semiconductor package structure shown in FIG. 5B further includes an electrical component 540d. As shown in FIG. 5B, the electrical component 540d is electrically connected to conductive pads 52f of the patterned conductive layer 52. The electrical component 540d is encapsulated by the encapsulation layer 55.

FIG. 5C is a schematic diagram illustrating a cross-sectional view of a semiconductor package structure according to some embodiments of the present disclosure. The semiconductor package structure shown in FIG. 5C is similar to the semiconductor package structure shown in FIG. 5A, except that the electrical component 540b is replaced by a die 58b, and that an encapsulation layer 55′ is further included. As shown in FIG. 5C, the die 58b is electrically connected to the conductive pads 53b through the electrical connection elements 592. Although not shown in FIG. 5C, the die 58b may include a plurality connection pins, and that the plurality connection pins of the die 58b are electrically connected to the conductive pads 53b through the electrical connection element 592. The encapsulation layer 55′ encapsulates electrical components 540a, 540b and the die 58b. The encapsulation layer 55′ may include an epoxy, a filler, or other suitable materials.

FIG. 5D is a schematic diagram illustrating a cross-sectional view of a semiconductor package structure according to some embodiments of the present disclosure. The semiconductor package structure shown in FIG. 5D is similar to the semiconductor package structure shown in FIG. 5B, except that the electrical component 540b is replaced by a die 58b, that the electrical components 540a and 540c are omitted, and that an encapsulation layer 55′ is further included. As shown in FIG. 5D, the die 58b is electrically connected to the conductive pads 53b through electrical connection elements 592. The encapsulation layer 55′ encapsulates the die 58b.

FIG. 5E is a schematic diagram illustrating a cross-sectional view of a semiconductor package structure according to some embodiments of the present disclosure. The semiconductor package structure shown in FIG. 5E is similar to the semiconductor package structure shown in FIG. 5D, except that the die 58a is replaced by an electrical component 540e. As shown in FIG. 5E, the electrical component 540e is electrically connected to the conductive pads 52e.

FIG. 5F is a schematic diagram illustrating a cross-sectional view of a semiconductor package structure according to some embodiments of the present disclosure. The semiconductor package structure shown in FIG. 5F is similar to the semiconductor package structure shown in FIG. 5C, except that a semiconductor package pg1 (which includes the substrate 500, the patterned conductive layer 52, the electrical connection element 57, the stud bump 56, the electrical component 540d, the die 58a, the metal finishing layer 54, the patterned conductive layer 53, and the encapsulation layer 55) as shown in FIG. 5F further includes an electrical component 540d that is electrically connected to conductive pads 52f of the patterned conductive layer 52.

FIG. 5G is a schematic diagram illustrating a cross-sectional view of a semiconductor package structure according to some embodiments of the present disclosure. The semiconductor package structure shown in FIG. 5G is similar to the semiconductor package structure shown in FIG. 5E, except that the semiconductor package structure shown in FIG. 5G further includes electrical components 540a and 540c. The electrical components 540a and 540c are electrically connected to the conductive pads 53a and 53c, respectively.

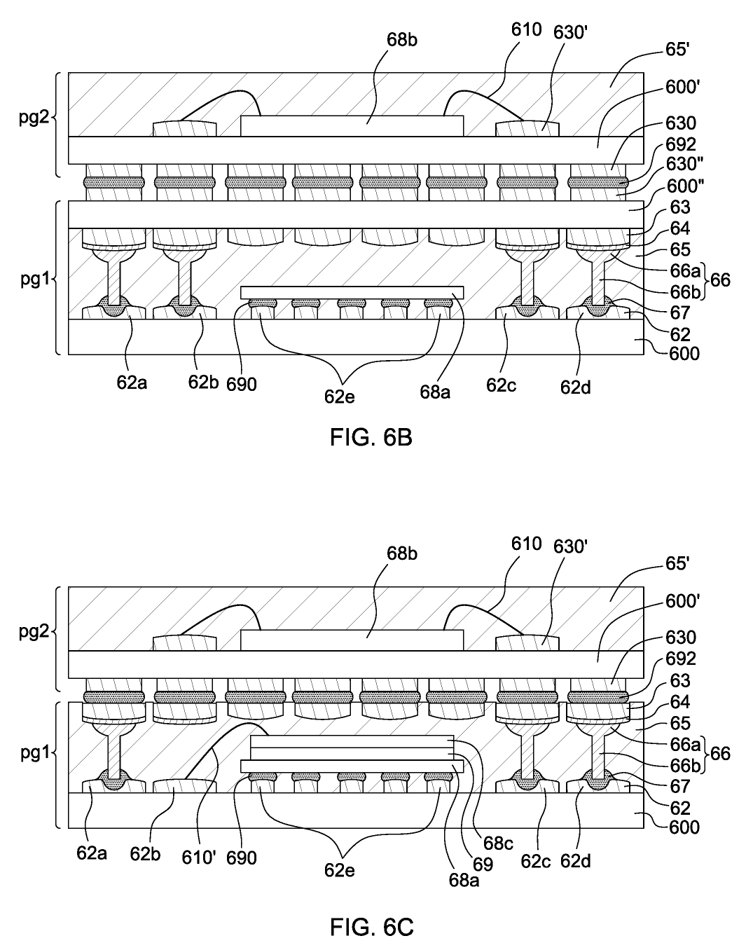

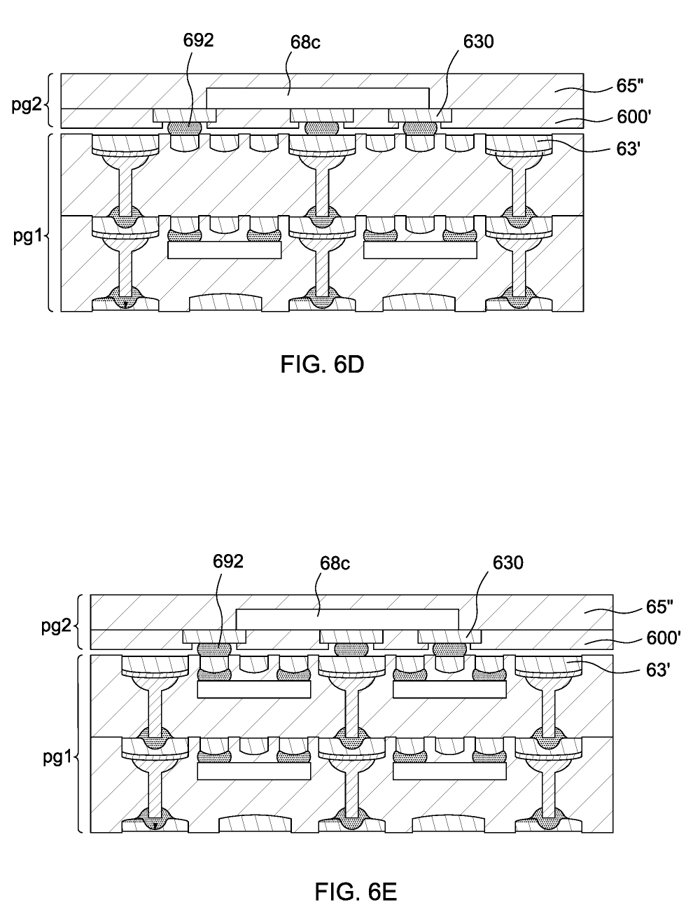

FIG. 6A is a schematic diagram illustrating a cross-sectional view of a semiconductor package structure according to some embodiments of the present disclosure. Referring to FIG. 6A, the semiconductor package structure includes a semiconductor package pg1 and a semiconductor package pg2. The semiconductor package pg1 includes a patterned conductive layer 62, a patterned conductive layer 63, a metal finishing layer 64, an encapsulation layer 65, a stud bump 66, an electrical connection element 67, a die 68a, and a substrate 600. The semiconductor package pg2 includes a patterned conductive layer 630, a patterned conductive layer 630′, an encapsulation layer 65′, a die 68b, and a substrate 600′.

Referring to FIG. 6A, the patterned conductive layer 62 includes conductive pads 62a, 62b, 62c, 62d and 62e. Although not shown in FIG. 6A, in some embodiments, the patterned conductive layer 62 may further include one or more traces disposed between the conductive pads. The patterned conductive layer 63 includes one or more conductive pads and one or more traces disposed between the conductive pads. The stud bump 66 includes a bump portion 66a and a stud portion 66b. The width of the bump portion 66a is greater than the width of the stud portion 66b (e.g. by a factor of about 1.2 or more, about 1.5 or more, or about 2.0 or more). The conductive pad 62a includes a portion 62a1 and a portion 62a2. In some embodiments, the portion 62a1 defines a recess, a dimple, or a cup shape. The conductive pads 62b, 62c and 62d are substantially in the same shape as the conductive pad 62a. The encapsulation layer 65 encapsulates the patterned conductive layer 62, the patterned conductive layer 63, the metal finishing layer 64, the stud bump 66, the electrical connection element 67, and the die 68a. The encapsulation layer 65 may include an epoxy, a filler, or other suitable materials.

The bump portion 66a is electrically connected to (and, for example, in contact with) the metal finishing layer 64, and the stud portion 66b is electrically connected to (and, for example, in contact with) the electrical connection element 67. In some embodiments, the metal finishing layer 64 may be omitted so that the bump portion 66a is electrically connected to (and, for example, in contact with) a conductive pad of the patterned conductive layer 63. The electrical connection element 67 is disposed within the portion 62a1 (e.g. within the recess defined by the portion 62a1) and is electrically connected to (and, for example, in contact with) the conductive pad 62a. In some embodiments, the electrical connection elements 67 may include solder material, for example, tin (Sn), another metal or other suitable material. Although not shown in FIG. 6A, in some embodiments, an intermetallic compound is formed between the electrical connection element 67 and the portion 62a1. The die 68a is electrically connected to the conductive pads 62e through electrical connection elements 690.

Referring to FIG. 6A, the back surface of the die 68b is mounted on the substrate 600′, and the active surface of the die 68b is electrically connected to the patterned conductive layer 630′ via wire connections 610. The semiconductor package pg1 is electrically connected to the semiconductor package pg2 through electrical connection elements 692 disposed between the patterned conductive layer 63 and the patterned conductive layer 630.

FIG. 6B is a schematic diagram illustrating a cross-sectional view of a semiconductor package structure according to some embodiments of the present disclosure. The semiconductor package structure shown in FIG. 6B is similar to the semiconductor package structure shown in FIG. 6A, except that the semiconductor package pg1 shown in FIG. 6B further includes a substrate 600″ and a patterned conductive layer 630″ on the substrate 600″. The semiconductor package pg1 is electrically connected to the semiconductor package pg2 through electrical connection elements 692 disposed between the patterned conductive layer 630 and the patterned conductive layer 630″.

FIG. 6C is a schematic diagram illustrating a cross-sectional view of a semiconductor package structure according to some embodiments of the present disclosure. The semiconductor package structure shown in FIG. 6C is similar to the semiconductor package structure shown in FIG. 6A, except that the semiconductor package pg1 of FIG. 6C further includes a die 68c, that the stud bump 66 and the electrical connection element 67 on the conductive pad 62b are omitted, and that the conductive pads 62b do not define a recess portion. Referring to FIG. 6C, the back surface of the die 68c is attached to the back surface of the die 68a via an adhesive layer 69. The active surface of the die 68c is electrically connected to the conductive pad 62b via a wire connection 610′.

FIG. 6D is a schematic diagram illustrating a cross-sectional view of a semiconductor package structure according to some embodiments of the present disclosure. Referring to FIG. 6D, the semiconductor package structure includes a semiconductor package pg1 and a semiconductor package pg2. The semiconductor package pg1 is identical to the semiconductor package structure shown in FIG. 1D. The semiconductor package pg2 includes a substrate 600′, a patterned conductive layer 630, an encapsulation layer 65″ and a die 68c. Referring to FIG. 6D, at least a portion of the patterned conductive layer 630 is exposed by the substrate 600′. The semiconductor package pg1 is electrically connected to the semiconductor package pg2 through electrical connection elements 692 disposed between the patterned conductive layer 630 and the patterned conductive layer 63′.

FIG. 6E is a schematic diagram illustrating a cross-sectional view of a semiconductor package structure according to some embodiments of the present disclosure. Referring to FIG. 6E, the semiconductor package structure includes a semiconductor package pg1 and a semiconductor package pg2. The semiconductor package pg1 is identical to the semiconductor package structure shown in FIG. 1E, and the semiconductor package pg2 of FIG. 6E is identical to the semiconductor package pg2 of FIG. 6D. Referring to FIG. 6E, the semiconductor package pg1 is electrically connected to the semiconductor package pg2 through electrical connection elements 692 disposed between the patterned conductive layer 630 and the patterned conductive layer 63′.

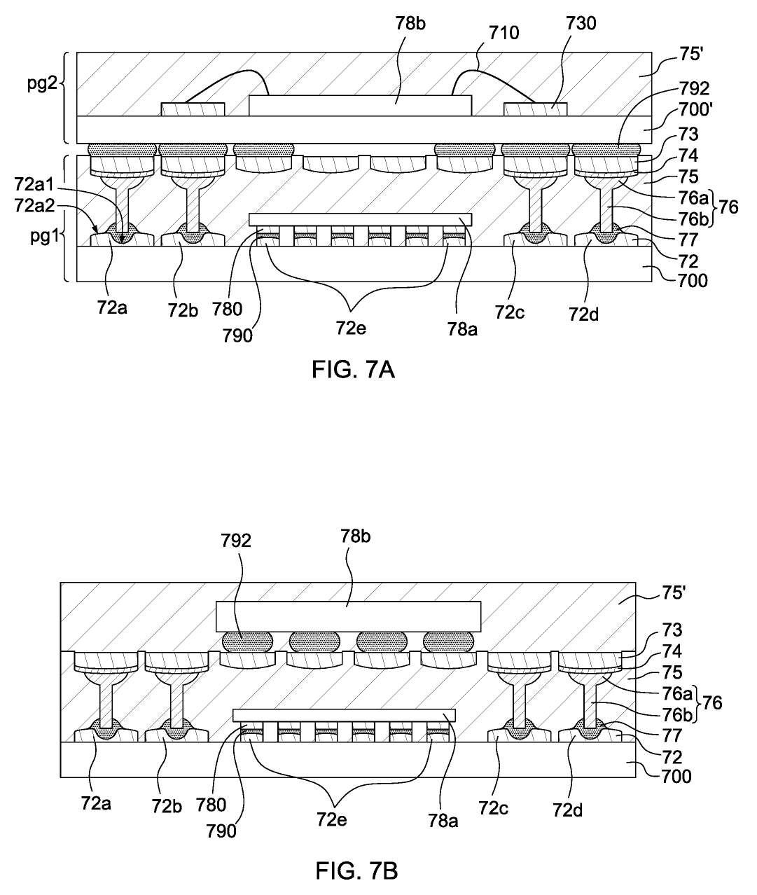

FIG. 7A is a schematic diagram illustrating a cross-sectional view of a semiconductor package structure according to some embodiments of the present disclosure. Referring to FIG. 7A, the semiconductor package structure includes a semiconductor package pg1 and a semiconductor package pg2. The semiconductor package pg1 includes a patterned conductive layer 72, a patterned conductive layer 73, a metal finishing layer 74, an encapsulation layer 75, a stud bump 76, an electrical connection element 77, a die 78a and a substrate 700.

The patterned conductive layer 72 includes conductive pads 72a, 72b, 72c, 72d and 72e. Although not shown in FIG. 7A, in some embodiments, the patterned conductive layer 72 may further include one or more traces disposed between the conductive pads. The patterned conductive layer 73 includes one or more conductive pads and one or more traces disposed between the conductive pads. The stud bump 76 includes a bump portion 76a and a stud portion 76b. The width of the bump portion 76a is greater than the width of the stud portion 76b (e.g. by a factor of about 1.2 or more, about 1.5 or more, or about 2.0 or more). The conductive pad 72a includes a portion 72a1 and a portion 72a2. In some embodiments, the portion 72a1 defines a recess, a dimple, or a cup shape. The conductive pads 72b, 72c and 72d are substantially in the same shape as the conductive pad 72a. The encapsulation layer 75 encapsulates the patterned conductive layer 72, the patterned conductive layer 73, the metal finishing layer 74, the stud bump 76, the electrical connection element 77 and the die 78a. The encapsulation layer 75 may include an epoxy, a filler, or other suitable materials.

The metal finishing layer 74 is disposed on the patterned conductive layer 73. The bump portion 76a is electrically connected to (and, for example, in contact with) the metal finishing layer 74, and the stud portion 76b is electrically connected to (and, for example, in contact with) the electrical connection element 77. In some embodiments, the metal finishing layer 74 may be omitted so that the bump portion 76a is electrically connected to (and, for example, in contact with) a conductive pad of the patterned conductive layer 73. The electrical connection element 77 is disposed within the portion 72a1 (e.g. within the recess defined by the portion 72a1) and is electrically connected to (and, for example, in contact with) the conductive pad 72a. In some embodiments, the electrical connection elements 77 may include solder material, for example, tin (Sn), another metal or other suitable material. Although not shown in FIG. 7A, in some embodiments, an intermetallic compound is formed between the electrical connection element 77 and the portion 72a1.

Referring to FIG. 7A, the semiconductor package pg2 includes a patterned conductive layer 730, an encapsulation layer 75′, a die 78b and a substrate 700′. The active surface of the die 78b is electrically connected to the patterned conductive layer 730 via wire connections 710. The semiconductor package pg1 is electrically connected to the semiconductor package pg2 through electrical connection elements 792 disposed between the substrate 700′ and the patterned conductive layer 73.

FIG. 7B is a schematic diagram illustrating a cross-sectional view of a semiconductor package structure according to some embodiments of the present disclosure. The semiconductor package structure shown in FIG. 7B is similar to the semiconductor package structure shown in FIG. 5C, except that components corresponding to the electrical components 540a and 540b are omitted from the semiconductor package structure shown in FIG. 7B.

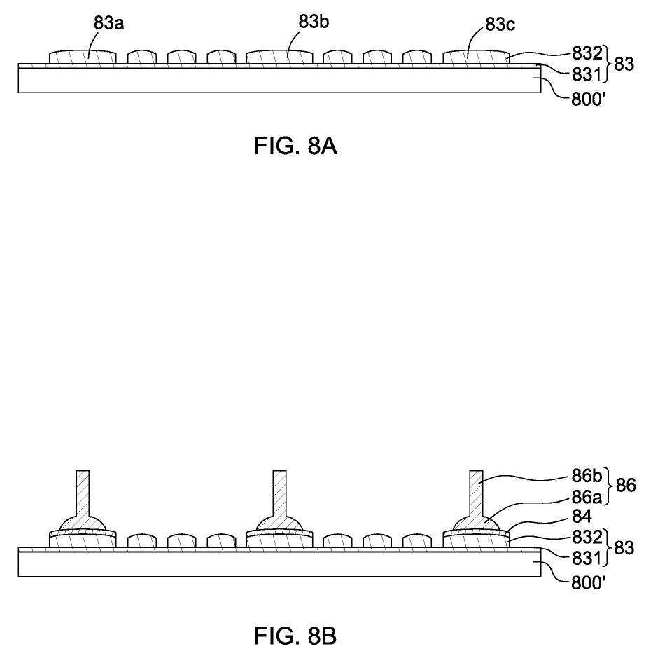

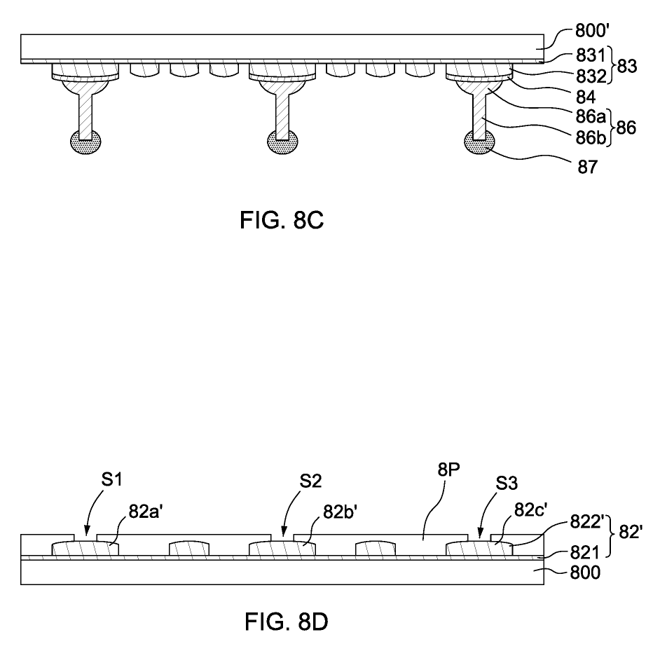

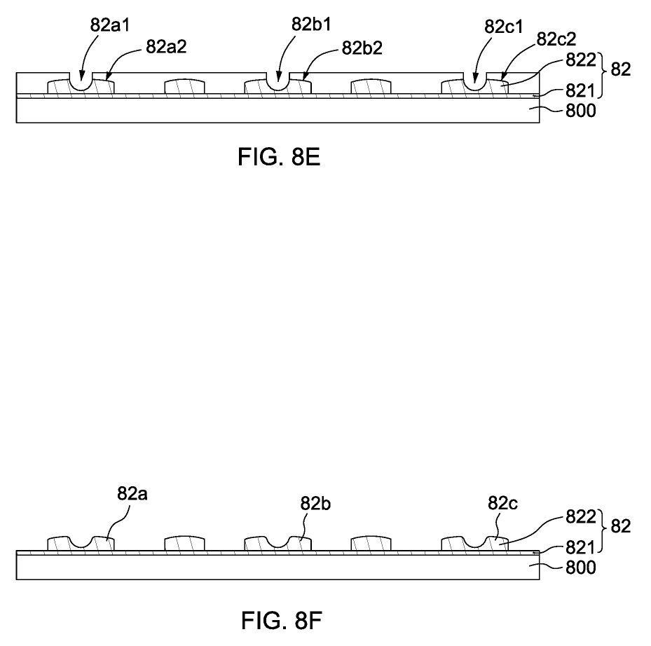

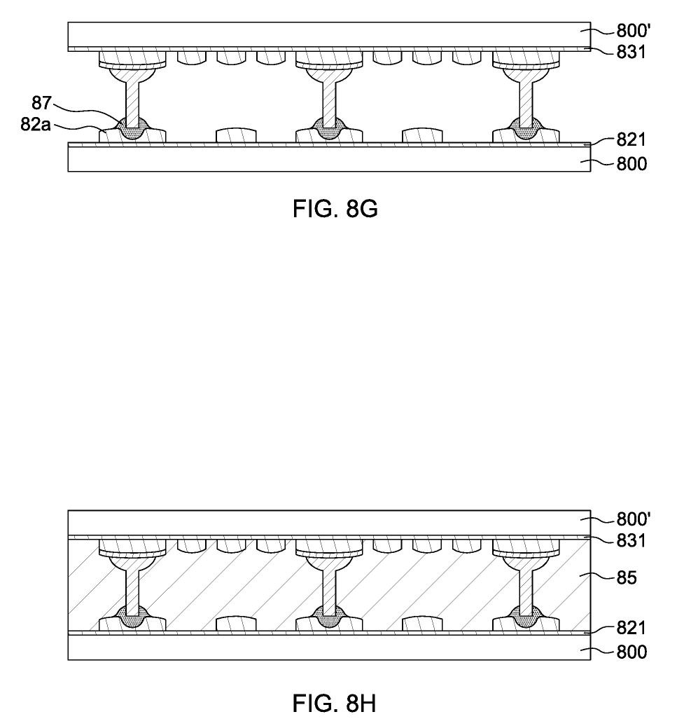

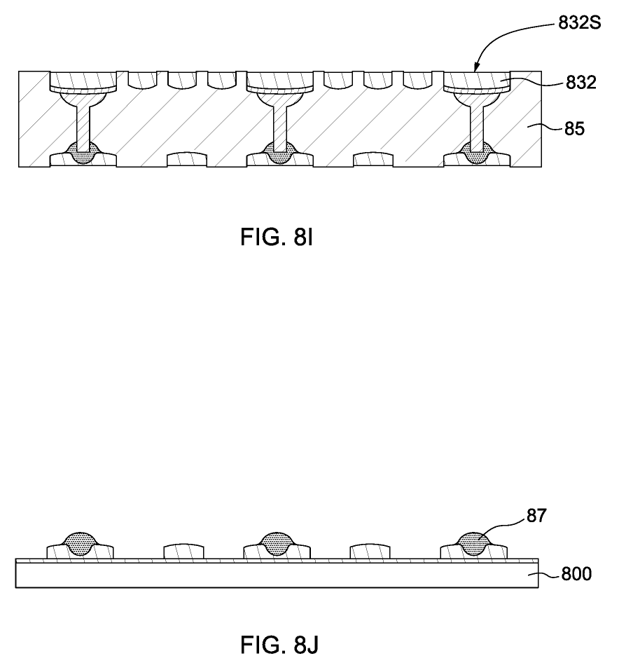

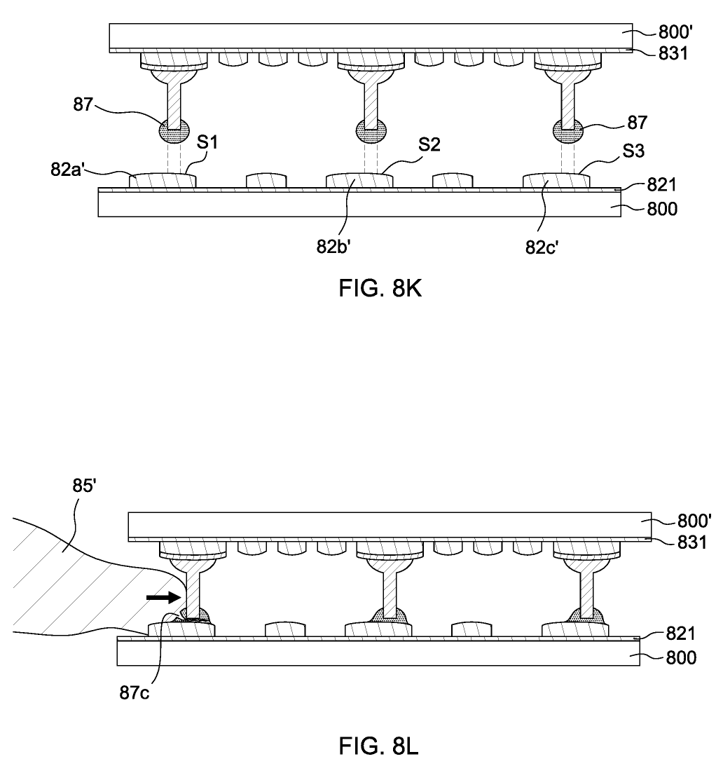

FIG. 8A through FIG. 8I illustrate a method of manufacturing a semiconductor package structure according to some embodiments of the present disclosure. The method discussed below may provide for a semiconductor package structure that includes through molding interconnections and high density circuit patterns. As shown in FIG. 8A, a carrier 800′ is provided, and a conductive layer 83 is disposed on an upper surface of the carrier 800′. The conductive layer 83 may include conductive material such as copper (Cu), other conductive metals, an alloy, or other suitable material. Referring to FIG. 8A, the conductive layer 83 includes a metal layer 831 and a patterned layer 832. The patterned layer 832 includes conductive pads 83a, 83b and 83c as well as the traces in between. In some embodiments, the patterned layer 832 is formed by a platting procedure. The patterned layer 832 further includes one or more traces disposed between the conductive pads.

As shown in FIG. 8B, a metal finishing layer 84 is provided (e.g. formed) on the conductive pads 83a, 83b and 83c, and then the stud bumps 86 are provided on the metal finishing layer 84 above the conductive pads 83a, 83b and 83c. In some embodiments, the metal finishing layer 84 may include conductive material, for example, nickel (Ni), gold (Au), an alloy, or other suitable material. In some embodiments, the metal finishing layer 84 may be omitted and the stud bumps 86 are provided directly on the conductive pads 83a, 83b and 83c.

Each of the stud bumps 86 includes a bump portion 86a and a stud portion 86b. In some embodiments, the stud bumps 86 are formed by wire bonding technique. The width of the bump portion 86a is greater than the width of the stud portion 86b (e.g. by a factor of about 1.2 or more, about 1.5 or more, or about 2.0 or more). The stud bumps 86 provide an excellent aspect ratio compared to a laser-formed via. In some embodiments, the width of the stud portion 86b is about 10 micrometers. In some embodiments, the width of the stud portion 86b is less than about 10 micrometers. In general, the width of a comparative Cu pillar that can be used as the interlayer interconnection in the semiconductor package is greater than 15 micrometers. In some embodiments, the stud bumps 86 have an aspect ratio of about 4:1. In some embodiments, the stud bumps 86 have an aspect ratio higher than about 4:1. In some embodiments, the stud bumps 86 have an aspect ratio of about 5:1. In some embodiments, the stud bumps 86 have an aspect ratio higher than about 5:1. In some embodiments, the stud bumps 86 have an aspect ratio of about 6:1. In some embodiments, the stud bumps 86 have an aspect ratio higher than about 6:1. For even greater aspect ratios, larger stud bump diameters may be employed.

As shown in FIG. 8C, electrical connection elements 87 are provided on the stud portion 86b of each stud bumps 86. In some embodiments, the electrical connection elements 87 are formed by a dipping procedure. In the dipping procedure, the stud portions 86b are dipped into a melted solder material and solder material is attached to each of the stud portions 86b. The volume of the solder material attached to the stud portion 86b depends on the width of the stud portion 86b. Since the width of the stud portion 86b is smaller compared to that of a Cu pillar, the volume of the solder material attached to the stud portion 86b is less than the volume of the solder material attached to a Cu pillar. That is, the volume of the electrical connection element 87 is less than the volume of a corresponding solder bump used on a Cu pillar. In some embodiments, the electrical connection elements 87 may include solder material, for example, tin (Sn), another metal or other suitable material.

As shown in FIG. 8D, a carrier 800 is provided, and a conductive layer 82′ is disposed on an upper surface of the carrier 800. The conductive layer 82′ may include conductive material such as copper (Cu), other conductive metals, an alloy, or other suitable material. Referring to FIG. 8D, the conductive layer 82′ includes a metal layer 821 and a patterned layer 822′. The patterned layer 822′ includes conductive pads 82a′, 82b′ and 82c′. The patterned layer 822′ includes one or more traces disposed between the conductive pads 82a′, 82b′ and 82c′. As shown in FIG. 8D, a patterned photoresist layer 8P is provided (e.g. formed) on the conductive layer 82′. The patterned photoresist layer 8P may include a dry-film photoresist formed using a lamination process and an exposure process. A portion of an upper surface S1 of the conductive pad 82a′ is exposed by the patterned photoresist layer 8P. A portion of an upper surface S2 of the conductive pad 82b′ is exposed by the patterned photoresist layer 8P. A portion of an upper surface S3 of the conductive pad 82c′ is exposed by the patterned photoresist layer 8P.

The upper surface S1 may be non-planar and has a first curvature. The upper surface S2 may be non-planar and has a second curvature. The upper surface S3 may be non-planar and has a third curvature. The first curvature, the second curvature and the third curvature may be formed naturally when the conductive pads 82a′, 82b′ and 82c′ are formed by pattern plating. In some embodiments, the first curvature, the second curvature and the third curvature are substantially the same. In some embodiments, the first curvature, the second curvature and the third curvature are different from each other.

Referring to FIG. 8E, portions of the patterned conductive layer 82′ are removed by an etching process. The etching process removes portions of the conductive pads 82a′, 82b′ and 82c′ and portions of the patterned photoresist layer 8P. The so-etched patterned conductive layer 82′ will hereinafter be referred to as a patterned conductive layer 82. Portions 82a1, 82b1 and 82c1 are formed in the conductive pads 82a′, 82b′ and 82c,′ respectively. In some embodiments, the portions 82a1, 82b1 and 82c1 each defines a recess, a dimple, or a cup shape. The so-etched upper surfaces S1, S2 and S3 will hereinafter be referred to as portions 82a2, 82b2 and 82c2. The so-etched conductive pads 82a′, 82b′ and 82c′ will hereinafter be referred to as conductive pads 82a, 82b and 82c. As shown in FIG. 8F, the patterned photoresist layer 8P is removed.

As shown in FIG. 8G, the carrier 800′ obtained in FIG. 8C is combined with, attached to, or joined with, the carrier 800 obtained in FIG. 8F. The carrier 800 is aligned with the carrier 800′. Each of the portions 82a1, 82b1 and 82c1 may function as a fiducial mark during the alignment of carriers 800 and 800′. Misalignment between carriers 800 and 800′ is mitigated or avoided by such use of the portions 82a1, 82b1 and 82c1. The electrical connection elements 87 are disposed within the portions 82a1, 82b1 and 82c1 of the conductive pads 82a, 82b and 82c. In some embodiments, the volume of each of the electrical connection elements 87 is substantially the same as the volume of each of the recesses of the portions 82a1, 82b1 and 82c1. In some embodiments, the volume of each of the electrical connection elements 87 is about two or less times the volume of each of the recesses of the portions 82a1, 82b1 and 82c1. In some embodiments, the volume of each of the electrical connection elements 87 is about three or less times the volume of each of the recesses of the portions 82a1, 82b1 and 82c1. In some embodiments, the volume of each of the electrical connection elements 87 is in the range of about one to about three times the volume of each of the recesses of the portions 82a1, 82b1 and 82c1.

Subsequent to a reflow operation or a heating operation, the electrical connection elements 87 are electrically connected to the conductive pads 82a, 82b and 82c. Although not shown in FIG. 8G, in some embodiments, an intermetallic compound may be formed between the electrical connection elements 87 and each of the portions 82a1, 82b1 and 82c1.

As shown in FIG. 8H, an encapsulation material is formed in a space between the carrier 800 and the carrier 800′ and thus an encapsulation layer 85 is formed. In some embodiments, the encapsulation layer 85 is formed by transfer molding. In the transfer molding procedure, the encapsulation material may flow laterally into the space between the carrier 800 and the carrier 800′.

Due to the design of each of the portions 82a1, 82b1 and 82c1, which define a recess, a dimple, or a cup, an intermetallic compound (IMC) (which may form in the recesses, the dimples, or the cups, and which is fragile and vulnerable to damage caused by mold flow of the encapsulation material) can be protected by each of the portions 82a1, 82b1 and 82c1. Due to the design of each of the portions 82a1, 82b1 and 82c1, which define a recess, a dimple, or a cup, the electrical connection element 87 may be constrained (e.g. during the reflow operation) which can help to avoid a short or a bridge issue.

As shown in FIG. 8I, the carriers 800 and 800′ are removed. The metal layers 821 and 831 are removed (e.g. by an etching technique). In some embodiments, an upper surface 832S of the patterned layer 832 may be lower than, or recessed from, the upper surface of the encapsulation layer 85 due to over-etching.

FIG. 8A, FIG. 8B, FIG. 8D, FIG. 8E, FIG. 8F, FIG. 8J, FIG. 8G, FIG. 8H and FIG. 8I illustrate a method of manufacturing a semiconductor package according to some embodiments of the present disclosure. The method which includes operations as shown in FIG. 8A, FIG. 8B, FIG. 8D, FIG. 8E, FIG. 8F, FIG. 8J, FIG. 8G, FIG. 8H and FIG. 8I is similar to the method which includes operations as shown in FIG. 8A, FIG. 8B, FIG. 8C, FIG. 8D, FIG. 8E, FIG. 8F, FIG. 8G, FIG. 8H and FIG. 8I, except that the operation of FIG. 8C is omitted, and that the operation shown in FIG. 8J is performed (e.g. subsequent to the operation shown in FIG. 8F). As shown in FIG. 8J, the electrical connection elements 87 are disposed in the portions 82a1, 82b1 and 82c1 of the conductive pads 82a, 82b and 82c.

FIG. 8A, FIG. 8B, FIG. 8C, FIG. 8D, FIG. 8K, FIG. 8L, FIG. 8H and FIG. 8I illustrate a comparative method of manufacturing a semiconductor package. The method which includes operations as shown in FIG. 8A, FIG. 8B, FIG. 8C, FIG. 8D, FIG. 8K, FIG. 8L, FIG. 8H and FIG. 8I is similar to the method which includes operations as shown in FIG. 8A, FIG. 8B, FIG. 8C, FIG. 8D, FIG. 8E, FIG. 8F, FIG. 8G, FIG. 8H and FIG. 8I, except that the operation of FIG. 8E is omitted, and that the patterned photoresist layer 8P is omitted in the operation of FIG. 8D. The operation shown in FIG. 8K is performed (e.g. subsequent to the operation shown in FIG. 8D). Misalignment between carriers 800 and 800′ may occur when bonding the carrier 800 to the carrier 800′, as shown in FIG. 8K. Besides that, the connection element (e.g. a solder material) may spread along the curved surface of the conductive pads 82a′, 82b′ and 82c′ during combination of, attachment of, or joining of, the carrier 800 and carrier 800′ so that the connection element between stud portion 86b and conductive pad 82b may be small and/or broken, and may even lead to an open circuit or an electrical disconnection between the electrical connection elements 87 and the conductive pads 82a′, 82b′ and 82c′.

In addition, in the operation as shown FIG. 8L, the mold flow of the encapsulation material 85′ between the carrier 800 and the carrier 800′ may move or push the stud bumps 86 (relatively to the conductive pads 82a′, 82b′ and 82c′) and cause a crack 87c in the electrical connection element 87 or in the intermetallic compound (IMC, which is not illustrated and denoted in FIG. 8L). The crack 87c may adversely affect performance of the semiconductor package structure, for example, the electrical connections between the electrical connection elements 87 and the conductive pads 82a′, 82b′ and 82c′ may be adversely affected. The crack 87c may result in an open circuit or electrical disconnection between the electrical connection elements 87 and the conductive pads 82a′, 82b′ and 82c′.

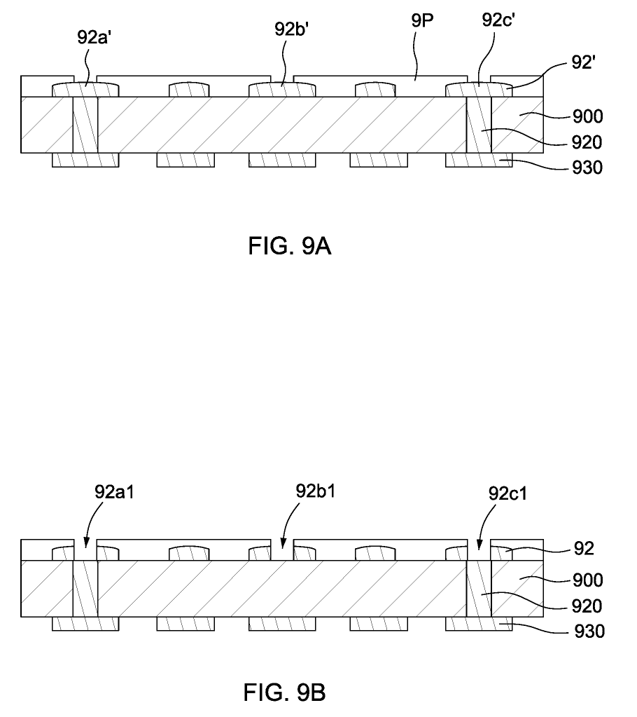

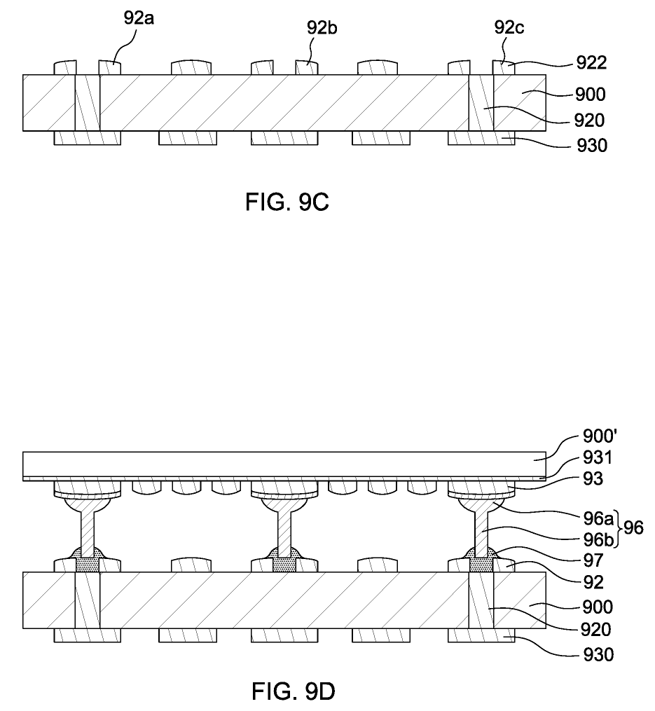

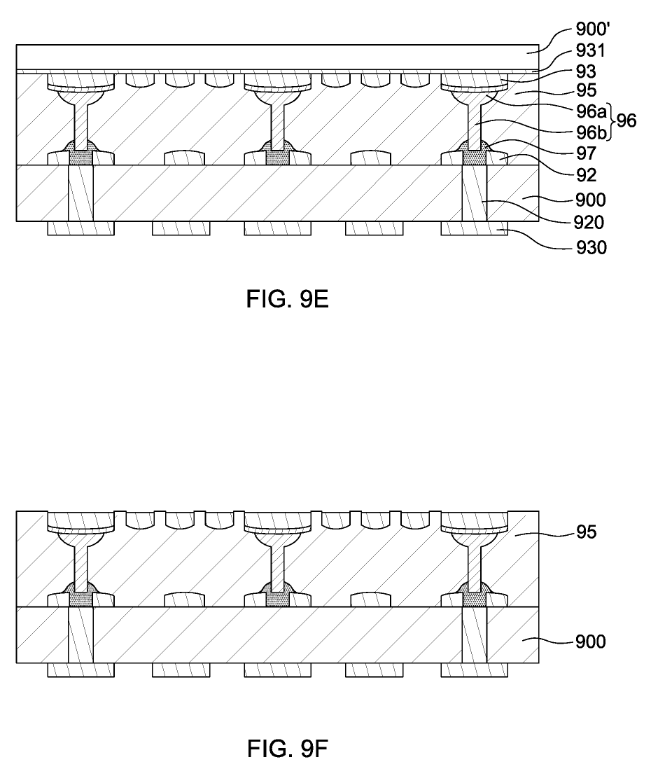

FIG. 9A through FIG. 9F illustrate a method of manufacturing a semiconductor package structure according to some embodiments of the present disclosure. As shown in FIG. 9A, a substrate 900 is provided. The substrate 900 includes a patterned conductive layer 92′ on a first surface of the substrate 900, a patterned conductive layer 930 on a second surface of the substrate 900 opposite to the first surface, a through via 920, and a patterned photoresist layer 9P. In some embodiments, through via 920 includes a laser via. The patterned conductive layer 92′ may include conductive material such as copper (Cu), other conductive metals, an alloy, or other suitable material. The patterned photoresist layer 9P may include a dry-film photoresist formed using a lamination process and an exposure process.

Referring to FIG. 9A, the patterned conductive layer 92′ includes conductive pads 92a′, 92b′ and 92c′. The patterned conductive layer 92′ includes one or more traces disposed between the conductive pads 92a′, 92b′ and 92c′. As shown in FIG. 9A, a portion of an upper surface of the conductive pad 92a′ is exposed by the patterned photoresist layer 9P. A portion of an upper surface of the conductive pad 92b′ is exposed by the patterned photoresist layer 9P. A portion of an upper surface of the conductive pad 92c′ is exposed by the patterned photoresist layer 9P.

As shown in FIG. 9B, portions of the patterned conductive layer 92′ are removed by an etching process. The etching process removes portions of the conductive pads 92a′, 92b′ and 92c′ and portions of the patterned photoresist layer 9P. The so-etched patterned conductive layer 92′ will hereinafter be referred to as a patterned conductive layer 92. Portions 92a1, 92b1 and 92c1 are formed in the conductive pads 92a′, 92b′ and 92c,′ respectively. The portions 92a1 and 92c1 expose the upper surface of through via 920 and the portion 92b1 exposes the upper surface of the substrate 900. In some embodiments, the portions 92a1, 92b1 and 92c1 each defines a recess, a dimple, or a cup shape. The so-etched conductive pads 92a′, 92b′ and 92c′ will hereinafter be referred to as conductive pads 92a, 92b and 92c. In some embodiments, from a top view the conductive pads 92a, 92b and 92c each have a donut shape. A shape of the etched recesses may be cup shaped and may have rounded corners, instead of the depicted rectangular shape. As shown in FIG. 9C, the patterned photoresist layer 9P is removed.

As shown in FIG. 9D, a carrier 900′ is combined with, attached to, or joined with, and aligned with the substrate 900 shown in FIG. 9C. The carrier 900′ can be assembled using the operations shown in FIGS. 8A through 8C. The electrical connection elements 97 are disposed within the portions 92a1, 92b1 and 92c1 of the conductive pads 92a, 92b and 92c. Subsequent to a reflow operation or a heating operation, the electrical connection elements 97 are electrically connected to the conductive pads 92a, 92b and 92c. As shown in FIG. 9E, an encapsulation material is filled in the space between the substrate 900 and the carrier 900,' and then an encapsulation layer 95 is formed. As shown in FIG. 9F, the carrier 900′ is removed, and then the metal layer 931 is also removed.

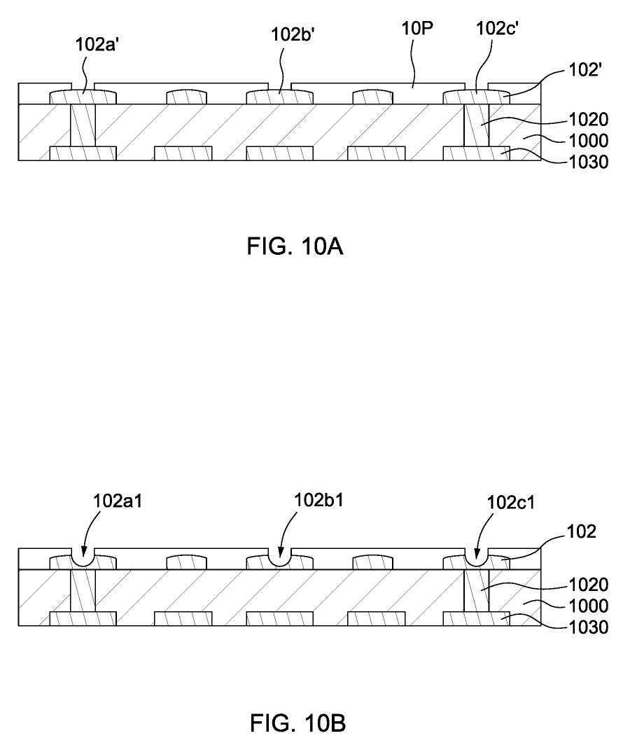

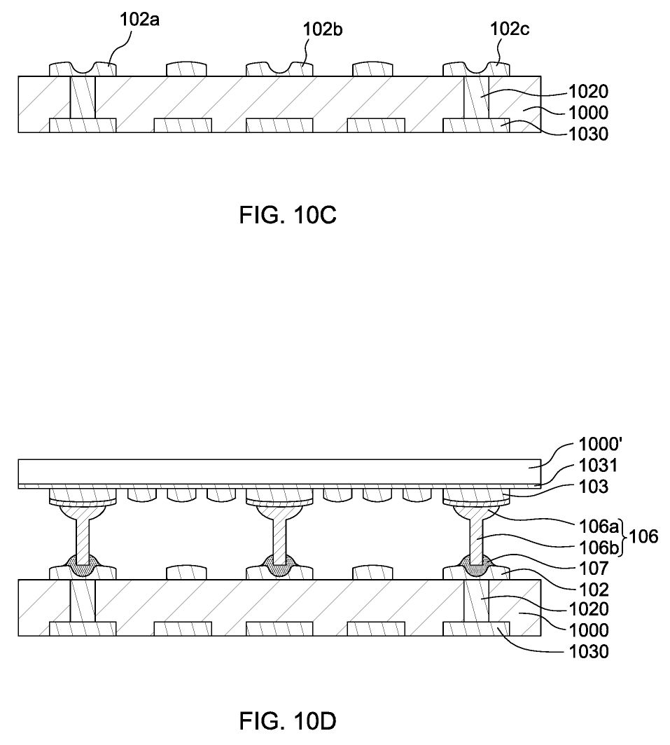

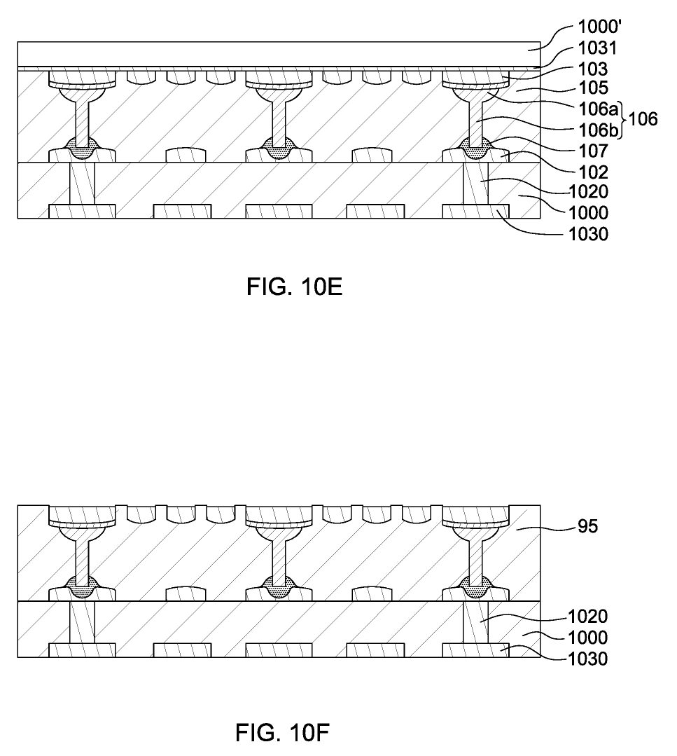

FIG. 10A through FIG. 1OF illustrate a method of manufacturing a semiconductor package structure according to some embodiments of the present disclosure. As shown in FIG. 10A, a substrate 1000 is provided. The substrate 1000 includes a patterned conductive layer 102′ on one surface of the substrate 1000, a patterned conductive layer 1030 embedded in substrate 1000, a conductive post 1020, and a patterned photoresist layer 10P. In some embodiments, the conductive post 1020 includes a laser via. In some embodiments, the conductive post 1020 includes a Cu pillar. The patterned conductive layer 102′ may include conductive material such as copper (Cu), other conductive metals, an alloy, or other suitable material. The patterned photoresist layer 10P may include a dry-film photoresist formed using a lamination process and an exposure process.

Referring to FIG. 10A, the patterned conductive layer 102′ includes conductive pads 102a′, 102b′ and 102c′. The patterned conductive layer 102′ includes one or more traces disposed between the conductive pads 102a′, 102b′ and 102c′. As shown in FIG. 10A, a portion of the upper surface of the conductive pad 102a′ is exposed by the patterned photoresist layer 10P. A portion of the upper surface of the conductive pad 102b′ is exposed by the patterned photoresist layer 10P. A portion of the upper surface of the conductive pad 102c′ is exposed by the patterned photoresist layer 10P.

As shown in FIG. 10B, portions of the patterned conductive layer 102′ are removed by an etching process. The etching process removes portions of the conductive pads 102a′, 102b′ and 102c′ and portions of the patterned photoresist layer 10P. The so-etched patterned conductive layer 102′ will hereinafter be referred to as a patterned conductive layer 102. Portions 102a1, 102b1 and 102c1 are formed in the conductive pads 102a′, 102b′ and 102c,′ respectively. In some embodiments, the portions 102a1, 102b1 and 102c1 each defines a recess, a dimple, or a cup shape. The so-etched conductive pads 102a′, 102b′ and 102c′ will hereinafter be referred to as conductive pads 102a, 102b and 102c. As shown in FIG. 10C, the patterned photoresist layer 10P is removed.

As shown in FIG. 10D, a carrier 1000′ is combined with, attached to, or joined with, and aligned with the substrate 1000 obtained in FIG. 10C. The carrier 1000′ can be assembled using the operations shown in FIGS. 8A through 8C. The electrical connection elements 107 are disposed within the portions 102a1, 102b1 and 102c1 of the conductive pads 102a, 102b and 102c. Subsequent to a reflow operation or a heating operation, the electrical connection elements 107 are electrically connected to the conductive pads 102a, 102b and 102c. As shown in FIG. 10E, an encapsulation material is filled in a space between the substrate 1000 and the carrier 1000,' and thus an encapsulation layer 105 is formed. As shown in FIG. 10F, the carrier 1000′ is removed, and then the metal layer 1031 is also removed.

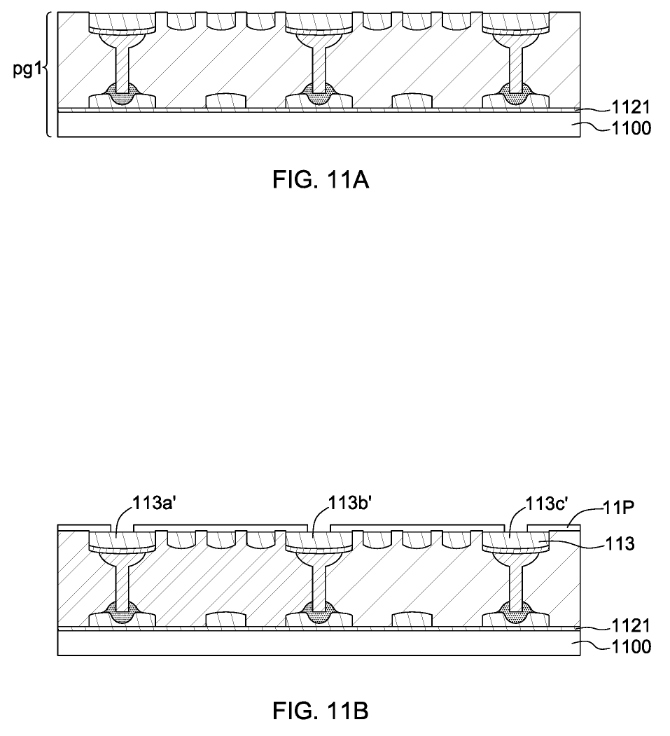

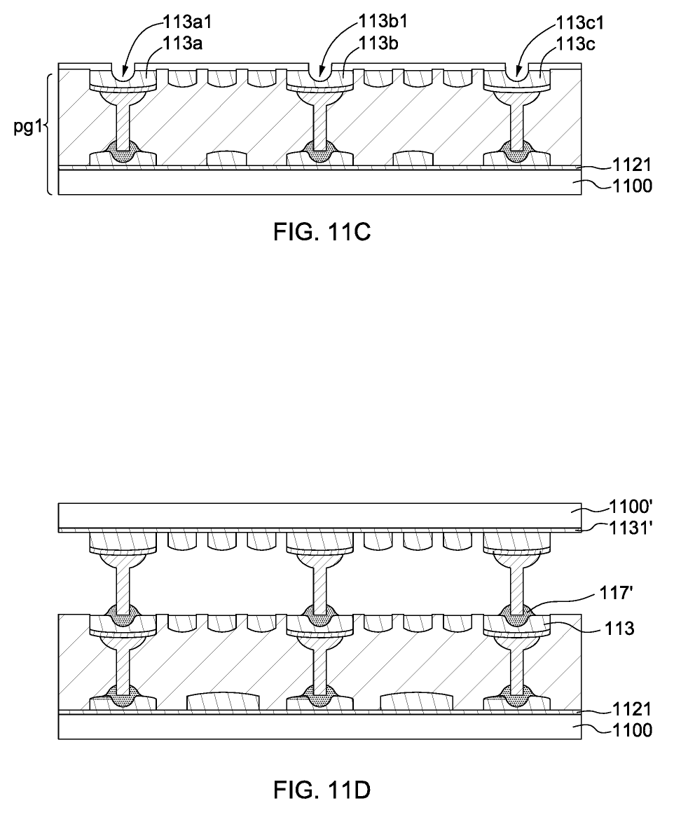

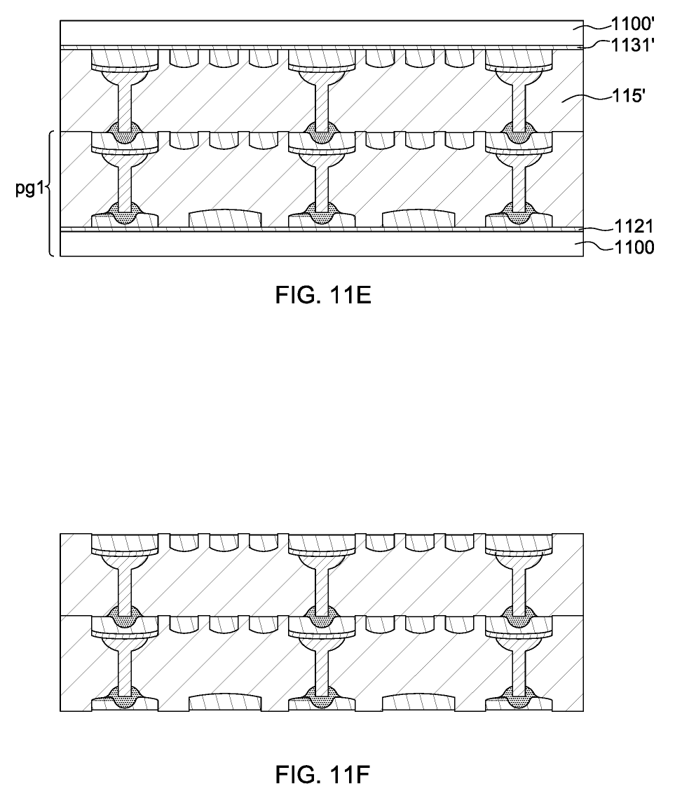

FIG. 11A through FIG. 11F illustrate a method of manufacturing a semiconductor package structure according to some embodiments of the present disclosure. As shown in FIG. 11A, a semiconductor package pg1 is provided. The semiconductor package of FIG. 11A is similar to that shown in FIG. 8H, except that the top carrier 800′ and the metal layer 831 are omitted or removed. As shown in FIG. 11B, a patterned photoresist layer 11P is formed. A portion of an upper surface of a conductive pad 113a′ is exposed by the patterned photoresist layer 11P. A portion of an upper surface of a conductive pad 113b′ is exposed by the patterned photoresist layer 11P. A portion of an upper surface of a conductive pad 113c′ is exposed by the patterned photoresist layer 11P.

As shown in FIG. 11C, portions of the conductive pads 113a′, 113b′ and 113c′ and portions of the patterned photoresist layer 11Pare removed by an etching process. Portions 113a1, 113b1 and 113c1 are formed in the conductive pads 113a′, 113b′ and 113c,′ respectively. In some embodiments, the portions 113a1, 113b1 and 113c1 each defines a recess, a dimple, or a cup shape. The so-etched conductive pads 113a′, 113b′ and 113c′ will hereinafter be referred to as conductive pads 113a, 113b and 113c.

As shown in FIG. 11D, the patterned photoresist layer 11P is removed, and a carrier 1100′ is combined with, attached to, or joined with, and aligned with the semiconductor package pg1 shown in FIG. 11C. The carrier 1100′ can be assembled using the operations shown in FIGS. 8A through 8C. The electrical connection elements 117′ are disposed within the portions 113a1, 113b1 and 113c1 of the conductive pads 113a, 113b and 113c. Subsequent to a reflow operation or a heating operation, the electrical connection elements 117′ are electrically connected to the conductive pads 113a, 113b and 113c.

As shown in FIG. 11E, an encapsulation material is filled in a space between the semiconductor package pg1 and the carrier 1100′, and thus an encapsulation layer 115′ is formed. As shown in FIG. 11F, the carriers 1100 and 1100′ are removed, and then the metal layers 1121 and 1131′ are also removed.

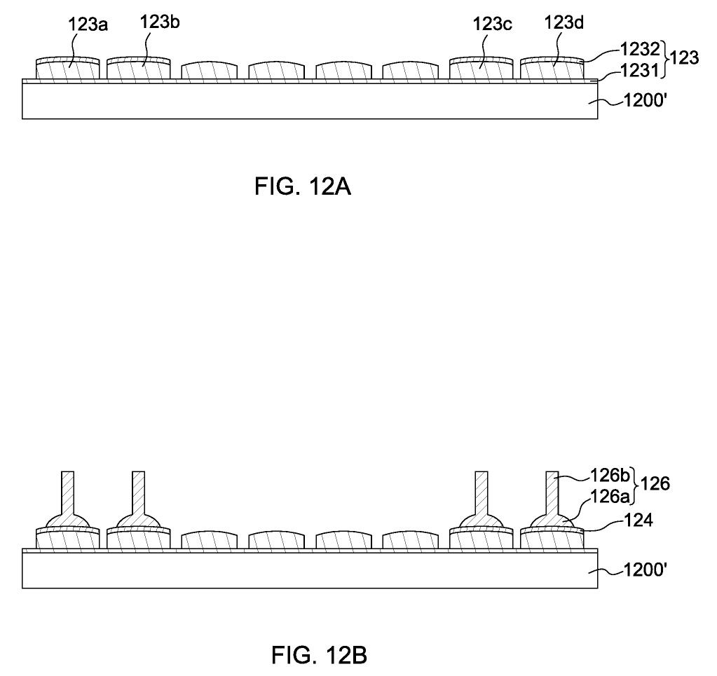

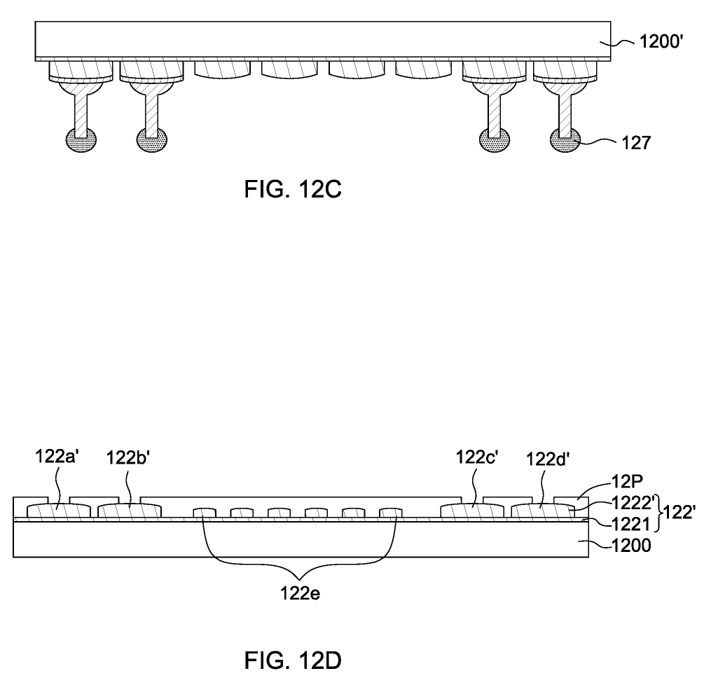

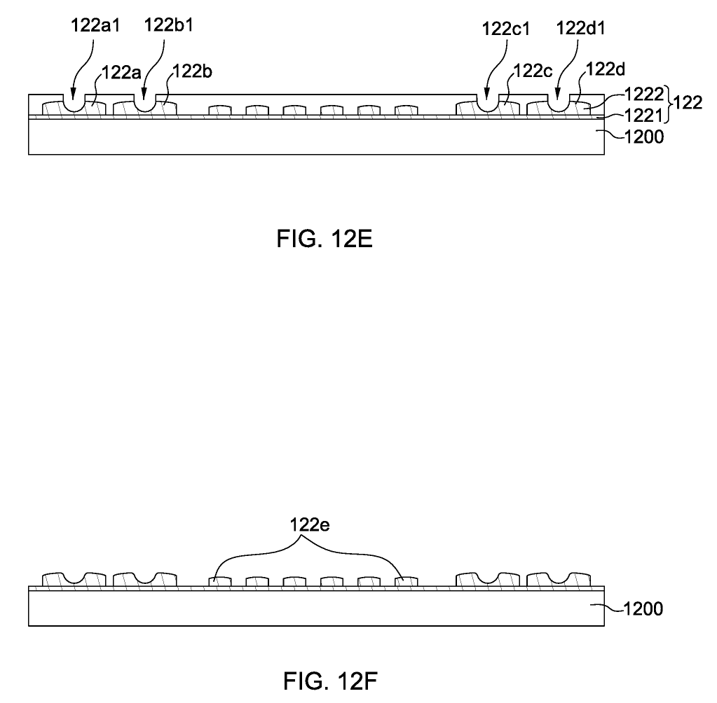

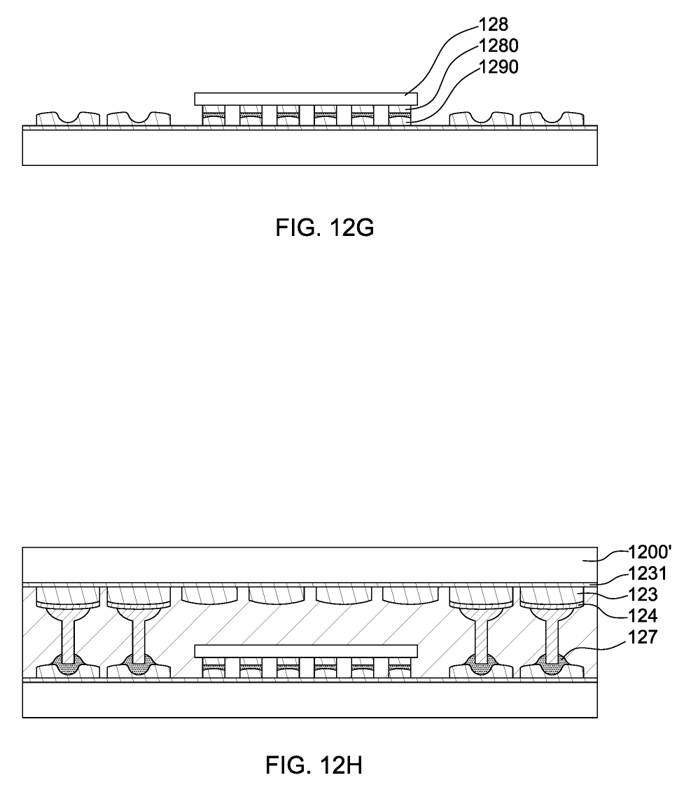

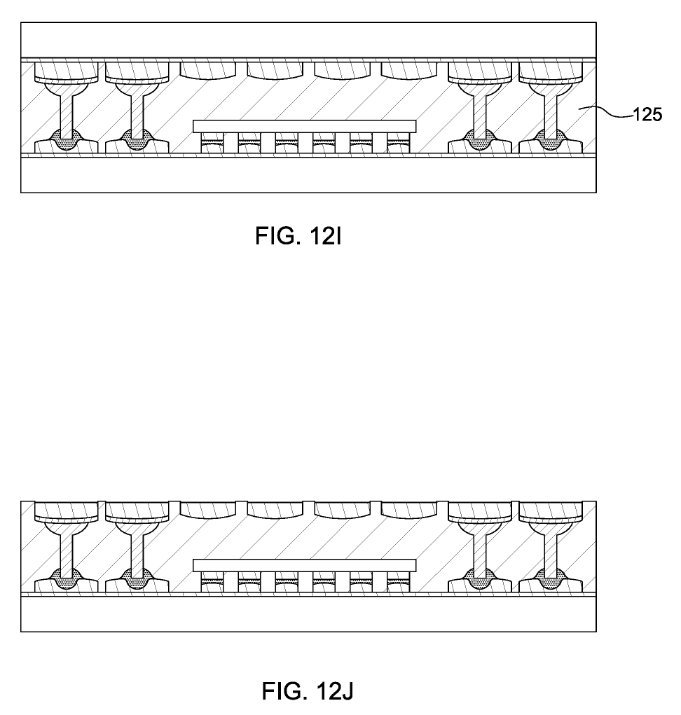

FIG. 12A through FIG. 12J illustrate a method of manufacturing a semiconductor package structure according to some embodiments of the present disclosure. As shown in FIG. 12A, a carrier 1200′ is provided, and a conductive layer 123 is disposed on an upper surface of the carrier 800′. The conductive layer 123 may include conductive material such as copper (Cu), other conductive metals, an alloy, or other suitable material. Referring to FIG. 12A, the conductive layer 123 includes a metal layer 1231 and a patterned layer 1232. The patterned layer 1232 includes conductive pads 123a, 123b, 123c and 123d. The patterned layer 1232 may include one or more traces disposed between the conductive pads 123b and 123c.

As shown in FIG. 12B, a metal finishing layer 124 is provided (e.g. formed) on the conductive pads 123a, 123b, 123c and 123d, and then stud bumps 126 are provided on the metal finishing layer 124 above the conductive pads 123a, 123b, 123c and 123d. Each of the stud bumps 126 includes a bump portion 126a and a stud portion 126b. The width of the bump portion 126a is greater than the width of the stud portion 126b (e.g. by a factor of about 1.2 or more, about 1.5 or more, or about 2.0 or more). As shown in FIG. 12C, electrical connection elements 127 are provided on the stud portion 126b of each stud bumps 126. In some embodiments, the electrical connection elements 127 are formed by a dipping procedure. In the dipping procedure, the stud portions 126b is dipped into a melted solder material and solder material is attached to each of the stud portions 126b. In some embodiments, the electrical connection elements 127 may include solder material, for example, tin (Sn), another metal or other suitable material.

As shown in FIG. 12D, a carrier 1200 is provided, and a conductive layer 122′ is disposed on an upper surface of the carrier 1200. The conductive layer 122′ may include conductive material such as copper (Cu), other conductive metals, an alloy, or other suitable material. Referring to FIG. 12D, the conductive layer 122′ includes a metal layer 1221 and a patterned layer 1222′. The patterned layer 1222′ includes conductive pads 122a′, 122b′, 122c′, 122d′ and 122e. As shown in FIG. 12D, a patterned photoresist layer 12P is provided (e.g. formed) on the conductive layer 122′. The patterned photoresist layer 12P may include a dry-film photoresist formed using a lamination process and an exposure process. A portion of the upper surface of each of the conductive pads 122a′, 122b′, 122c′ and 122d′ is exposed by the patterned photoresist layer 12P.

Referring to FIG. 12E, portions of the conductive 122a′, 122b′, 122c′ and 122d′ are removed by an etching process. The so-etched conductive layer 122′ will hereinafter be referred to as a patterned conductive layer 122. Portions 122a1, 122b1, 122c1 and 122d1 are formed in the conductive pads 122a′, 122b′, 122c′ and 122d′, respectively. In some embodiments, the portions 122a1, 122b1 and 122c1 each defines a recess, a dimple, or a cup shape. The so-etched conductive pads 122a′, 122b′, 122c′ and 122d′ will hereinafter be referred to as conductive pads 122a, 122b, 122c and 122d. As shown in FIG. 12F, the patterned photoresist layer 12P is removed.

As shown in FIG. 12G, a die 128 including a plurality of connection pins 1280 is mounted on the conductive pads 122e. The connection pins 1280 are electrically connected to the conductive pads 122e through electrical connection elements 1290. As shown in FIG. 12H, a carrier 1200′ is combined with, attached to, or joined with, and aligned with the carrier 1200 obtained in FIG. 12G. The carrier 1200′ is obtained using the operations shown in FIGS. 12A through 12C. The electrical connection elements 127 are disposed within the portions 122a1, 122b1, 122c1 and 122d1 of the conductive pads 122a, 122b, 122c and 122d. Subsequent to a reflow operation or a heating operation, the electrical connection elements 127 are electrically connected to the conductive pads 122a, 122b, 122c and 122d.

As shown in FIG. 121, an encapsulation material is filled in a space between the carrier 1200 and the carrier 1200,′ and thus an encapsulation layer 125 is formed. As shown in FIG. 12J, the carrier 1200′ is removed, and the metal layer 1231 is also removed.

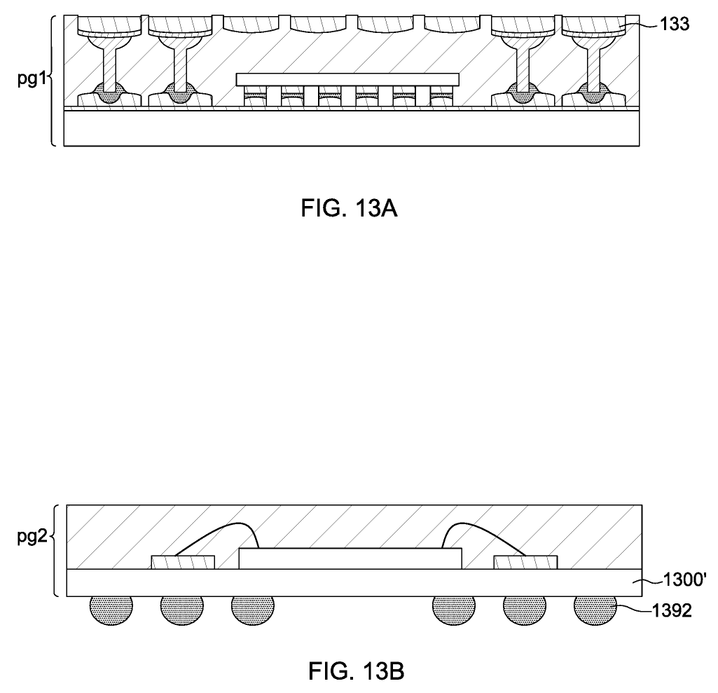

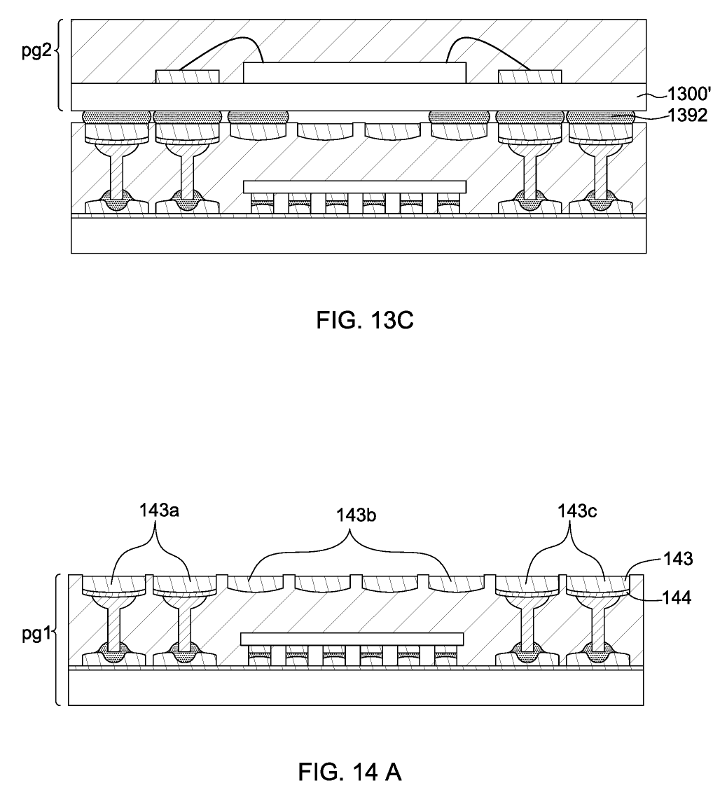

FIG. 13A through FIG. 13C illustrate a method of manufacturing a semiconductor package structure according to some embodiments of the present disclosure. The operations shown in FIGS. 13A through 13C may be implemented to manufacture the semiconductor package structure shown in FIG. 7A. In FIG. 13A, a semiconductor package pg1 is provided. The structure of the semiconductor package pg1 shown in FIG. 13A is identical to that of the semiconductor package pg1 shown in FIG. 7A. Referring to FIG. 13A, the semiconductor package pg1 includes a patterned conductive layer 133. The patterned conductive layer 133 includes one or more conductive pads and one or more traces disposed between the conductive pads. In FIG. 13B, a semiconductor package pg2 is provided. The structure of the semiconductor package pg2 shown in FIG. 13B is identical to that of the semiconductor package pg2 shown in FIG. 7A. In addition, a plurality of electrical connection elements 1392 are provided on the bottom surface of the substrate 1300′. In some embodiments, the electrical connection elements 1392 may include solder material, for example, tin (Sn), another metal or other suitable material. In FIG. 13C, the semiconductor package pg2 is mounted to the semiconductor package pg1 by electrically connecting the substrate 1300′ to the patterned conductive layer 133 through the electrical connection elements 1392.

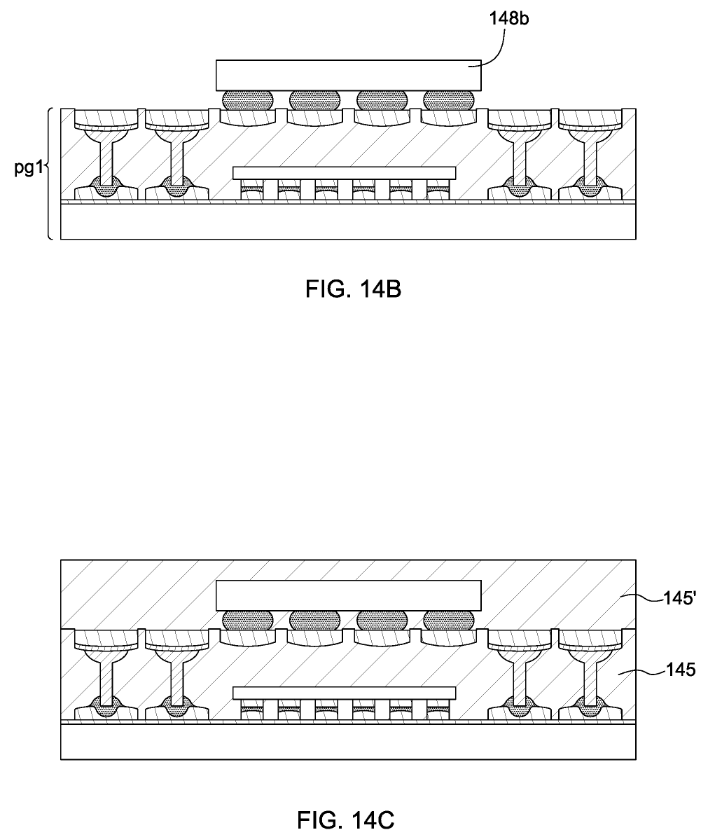

FIG. 14A through FIG. 14C illustrate a method of manufacturing a semiconductor package structure according to some embodiments of the present disclosure. The operations shown in FIGS. 14A through 14C may be implemented to manufacture the semiconductor package structure shown in FIG. 7B. In FIG. 14A, a semiconductor package pg1 is provided. The semiconductor package pg1 includes a patterned conductive layer 143 and a metal finishing layer 144. The patterned conductive layer 143 includes conductive pads 143a, 143b and 143c. The structure of the semiconductor package pg1 shown in FIG. 14A is identical to that of the semiconductor package shown in FIG. 12J. In FIG. 14B, a die 148b is mounted to the semiconductor package pg1 by electrically connecting the active surface of the die 148b to the conductive pads 143b thorough the electrical connection elements 1492. In some embodiments, the electrical connection elements 1492 may include solder material, for example, tin (Sn), another metal or other suitable material. In FIG. 14C, an encapsulation layer 145′ is provided (e.g. formed) above the semiconductor package pg1. The encapsulation layer 145′ encapsulates the die 148b and the electrical connection elements 1492. The encapsulation layer 145′ may include an epoxy, a filler, or other suitable materials.

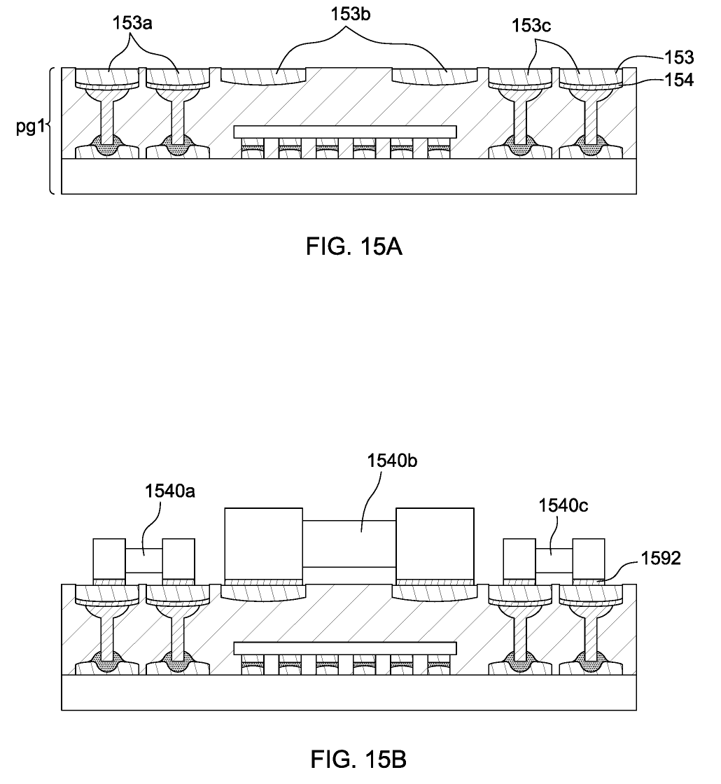

FIGS. 15A and 15B illustrate a method of manufacturing a semiconductor package structure according to some embodiments of the present disclosure. The operations shown in FIGS. 15A and 15B may be implemented to manufacture the semiconductor package structure shown in FIG. 5A. In FIG. 15A, a semiconductor package pg1 is provided. The semiconductor package pg1 includes a patterned conductive layer 153 and a metal finishing layer 154. The patterned conductive layer 153 includes conductive pads 153a, 153b and 153c. The structure of the semiconductor package pg1 shown in FIG. 15A is similar to that of the semiconductor package shown in FIG. 12J.

In FIG. 15B, electrical components 1540a, 1540b and 1540c are provided. The electrical component 1540a is electrically connected to the conductive pads 153a through the electrical connection elements 1592, the electrical component 1540b is electrically connected to the conductive pads 153b through the electrical connection elements 1592, and the electrical component 1540c is electrically connected to the conductive pads 153c through the electrical connection elements 1592. In some embodiments, the electrical connection elements 1592 may include solder material, for example, tin (Sn), another metal or other suitable material. In some embodiments, the electrical components 1540a, 1540b and 1540c include, but are not limited to, any of resistors, capacitors, inductors, transistors, tunnel diodes, metamaterial components, dissipative components or energy-neutral components.

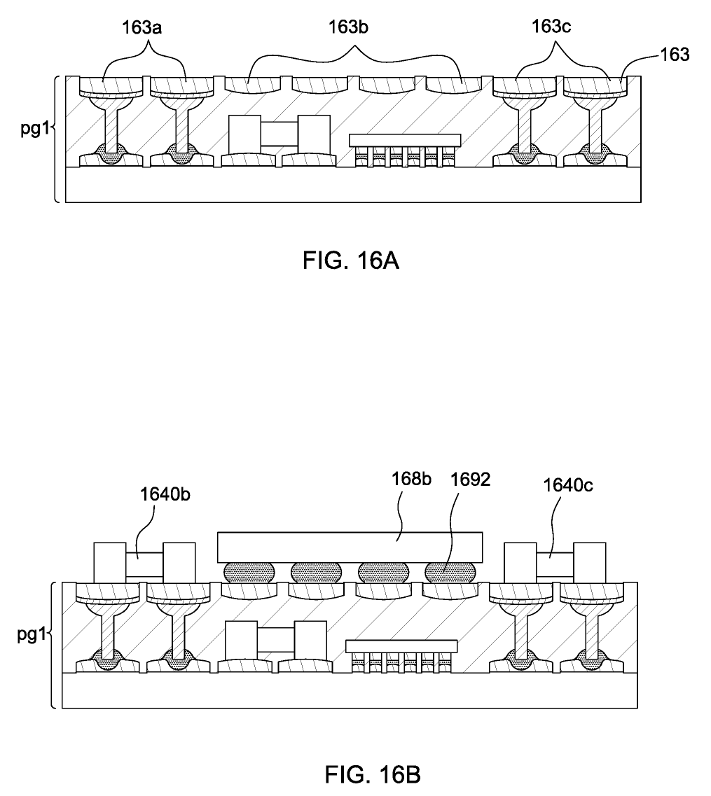

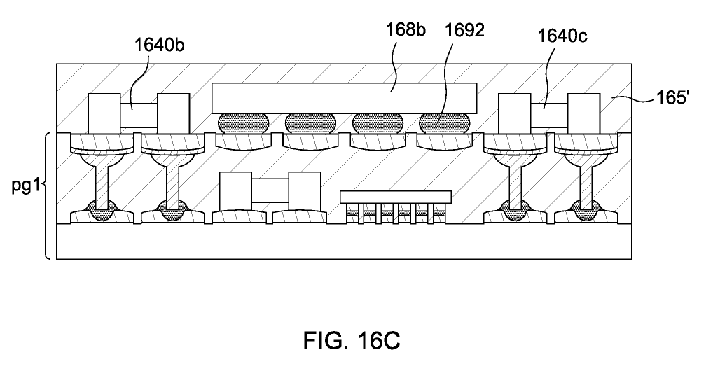

FIG. 16A through FIG. 16C illustrate a method of manufacturing a semiconductor package structure according to some embodiments of the present disclosure. The operations shown in FIGS. 16A through 16C may be implemented to manufacture the semiconductor package structure shown in FIG. 5F. In FIG. 16A, a semiconductor package pg1 is provided. The structure of the semiconductor package pg1 is identical to that of the semiconductor package pg1 shown FIG. 5F. The semiconductor package pg1 shown in FIG. 16A includes a patterned conductive layer 163. The patterned conductive layer 163 includes conductive pads 163a, 163b and 163c. In FIG. 16B, electrical connection elements 1692 are provided (e.g. formed) on one surface of the conductive pads 163b. In some embodiments, the electrical connection elements 1692 may include solder material, for example, tin (Sn), another metal or other suitable material. A die 168b is electrically connected to the conductive pads 163b through the electrical connection elements 1692, and then the electrical components 1640b and 1640c are electrically connected to the conductive pads 163a and 163c, respectively. Although not shown in FIG. 16B, electrical connection elements may be disposed between the electrical components 1640b and 1640c and the conductive pads 163a and 163c. In FIG. 16C, an encapsulation layer 165′ is provided (e.g. formed) above the semiconductor package pg1. The encapsulation layer 165′ encapsulates the die 168b, the electrical components 1640b and 1640c, and the electrical connection elements 1692. The encapsulation layer 165′ may include an epoxy, a filler, or other suitable materials.

As used herein, the singular terms “a,” “an,” and “the” may include plural referents unless the context clearly dictates otherwise. In the description of some embodiments, a component provided “on,” “above,” or “over” another component can encompass cases where the former component is directly on (e.g., in physical contact with) the latter component, as well as cases where one or more intervening components are located between the former component and the latter component.

As used herein, the terms “substantially,” “approximately,” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, the term “about” or “substantially” equal in reference to two values can refer to a ratio of the two values being within a range between and inclusive of 0.9 and 1.1

Additionally, amounts, ratios, and other numerical values are sometimes presented herein in a range format. It is to be understood that such a range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations do not limit the present disclosure. It should be understood by those skilled in the art that various changes may be made and equivalents may be substituted without departing from the true spirit and scope of the present disclosure, as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

1. A semiconductor package structure, comprising:
a first patterned conductive layer comprising a first conductive pad, a second conductive pad and a first conductive trace disposed between the first conductive pad and the second conductive pad, the first conductive pad defining a recess;
a second patterned conductive layer comprising a third conductive pad;
a first stud bump electrically connecting the first conductive pad of the first patterned conductive layer to the third conductive pad of the second patterned conductive layer; and
a first encapsulation layer disposed between the first patterned conductive layer and the second patterned conductive layer.

2. The semiconductor package structure of claim 1, wherein the first stud bump comprises a first portion and a second portion, and a width of the first portion is greater than a width of the second portion.

3. The semiconductor package structure of claim 2, further comprising a metal finishing layer disposed on the third conductive pad of the second patterned conductive layer.

4. The semiconductor package structure of claim 3, further comprising an electrical connection element disposed in the recess of the first conductive pad.

5. The semiconductor package structure of claim 4, wherein the first portion of the first stud bump is electrically connected to the metal finishing layer and the second portion of the first stud bump is electrically connected to the electrical connection element.

6. The semiconductor package structure of claim 4, wherein a volume of the electrical connection element is in a range of one to three times a volume of the recess.

7. The semiconductor package structure of claim 1, wherein the first encapsulation layer includes at least one of an epoxy or a filler.

8. The semiconductor package structure of claim 1, wherein the first stud bump has an aspect ratio of higher than 4:1.

9. The semiconductor package structure of claim 1, further comprising a die having a back surface and an active surface, wherein the back surface of the die is attached to the second conductive pad of the first patterned conductive layer, and the active surface of the die is electrically connected to the first conductive trace.

10. The semiconductor package structure of claim 1, further comprising a die including a plurality of connection pins, wherein the first patterned conductive layer further comprises a plurality of second conductive pads including the second conductive pad, and the plurality of connection pins are electrically connected to the plurality of second conductive pads of the first patterned conductive layer.

11. The semiconductor package structure of claim 1, further comprising:
a third patterned conductive layer comprising a fourth conductive pad;
a second encapsulation layer disposed between the second patterned conductive layer and the third patterned conductive layer; and
a second stud bump; wherein
the third conductive pad of the second patterned conductive layer defines a recess, and
the second stud bump electrically connects the third conductive pad of the second patterned conductive layer to the fourth conductive pad of the third patterned conductive layer.

12. The semiconductor package structure of claim 11, further comprising a first die, the first die is electrically connected to the second patterned conductive layer.

13. The semiconductor package structure of claim 12, further comprising a semiconductor package including a second die, wherein the semiconductor package is electrically connected to the third patterned conductive layer.

14. The semiconductor package structure of claim 12, further comprising a second die, the second die is electrically connected to the third patterned conductive layer.

15. The semiconductor package structure of claim 14, further comprising a semiconductor package including a third die, wherein the semiconductor package is electrically connected to the third patterned conductive layer.

16. The semiconductor package structure of claim 1, wherein the first encapsulation layer has a first surface and a second surface opposite to the first surface, wherein the first patterned conductive layer is embedded in the first surface of the first encapsulation layer and the second patterned conductive layer is embedded in the second surface of the first encapsulation layer.

17. The semiconductor package structure of claim 16, further comprising:
a substrate having a first surface and a second surface opposite to the first surface, the first surface of the substrate adjacent to the first surface of the first encapsulation layer;
a third patterned conductive layer disposed on the second surface of the substrate; and
a through via; wherein
the through via penetrates the substrate and electrically connects a portion of the third patterned conductive layer to a portion of the first patterned conductive layer.

18. The semiconductor package structure of claim 17, further comprising a die having a back surface and an active surface, the back surface of the die is attached to the second conductive pad of the first patterned conductive layer, and the active surface of the die is electrically connected to a portion of the first patterned conductive layer.

19. The semiconductor package structure of claim 17, further comprising a die including a plurality of connection pins, wherein the first patterned conductive layer further comprises a plurality of second conductive pads including the second conductive pad, and the plurality of connection pins are electrically connected to the plurality of second conductive pads of the first patterned conductive layer.

20. The semiconductor package structure of claim 17, further comprising:
a fourth patterned conductive layer;
a second encapsulation layer disposed between the second patterned conductive layer and the fourth patterned conductive layer; and
a second stud bump; wherein
the third conductive pad of the second patterned conductive layer defines a recess, and
the second stud bump electrically connects a portion of the second patterned conductive layer to a portion of the fourth patterned conductive layer.

21. The semiconductor package structure of claim 20, further comprising:
a first die and a second die, wherein the first die is electrically connected to a portion of the first patterned conductive layer, and the second die is electrically connected to a portion of the second patterned conductive layer.

22. The semiconductor package structure of claim 16, further comprising:
a die;
a substrate having a first surface and a second surface opposite to the first surface, the first surface of the substrate adjacent to the second surface of the first encapsulation layer;
a third patterned conductive layer disposed on the second surface of the substrate; and
a through via penetrating the substrate and electrically connecting a portion of the third patterned conductive layer to a portion of the second patterned conductive layer; wherein
the die is electrically connected to a portion of the first patterned conductive layer.

23. The semiconductor package structure of claim 16, further comprising:
a first substrate having a first surface and a second surface opposite to the first surface, the second surface of the first substrate adjacent to the first surface of the first encapsulation layer;
a third patterned conductive layer embedded in the first surface of the first substrate; and
a first through via penetrating the first substrate and electrically connects a portion of the third patterned conductive layer to a portion of the first patterned conductive layer.

24. The semiconductor package structure of claim 23, further comprising a die having a back surface and an active surface, the back surface of the die attached to the second conductive pad of the first patterned conductive layer, and the active surface of the die electrically connected to a portion of the first patterned conductive layer.

25. The semiconductor package structure of claim 23, further comprising a die comprising a plurality of connection pins, wherein the first patterned conductive layer further comprises a plurality of second conductive pads including the second conductive pad, and the plurality of connection pins are electrically connected to the plurality of second conductive pads of the first patterned conductive layer.

26. The semiconductor package structure of claim 23, further comprising:
a second stud bump;
a second through via;
a second substrate having a first surface and a second surface opposite to the first surface, the second surface of the second substrate adjacent to the first surface of the first substrate;
a fourth patterned conductive layer;
a fifth patterned conductive layer embedded in the first surface of the second substrate; and
a second encapsulation layer disposed between the second patterned conductive layer and the fourth patterned conductive layer; wherein
the third conductive pad of the second patterned conductive layer defines a recess,
the second stud bump electrically connects the third conductive pad of the second patterned conductive layer to a portion of the fourth patterned conductive layer, and
the second through via penetrates the second substrate and electrically connects a portion of the third patterned conductive layer to a portion of the fifth patterned conductive layer.

27. The semiconductor package structure of claim 16, further comprising:
a first die;
a through via;
a substrate having a first surface and a second surface opposite to the first surface, the first surface of the substrate adjacent to the second surface of the first encapsulation layer; and
a third patterned conductive layer embedded in the second surface of the substrate; wherein
the first die is electrically connected to a portion of the first patterned conductive layer, and
the through via penetrates the substrate and electrically connects a portion of the third patterned conductive layer to a portion of the second patterned conductive layer.

28. The semiconductor package structure of claim 27, further comprising:
a second die;
a fourth patterned conductive layer;
a second encapsulation layer disposed between the second patterned conductive layer and the fourth patterned conductive layer; and
a second stud bump; wherein
the second die is electrically connected to a portion of the second patterned conductive layer,
the third conductive pad of the second patterned conductive layer defines a recess, and
the second stud bump electrically connects the third conductive pad of the second patterned conductive layer to a portion of the fourth patterned conductive layer.

29. The semiconductor package structure of claim 16, further comprising:
a first substrate having a first surface and a second surface opposite to the first surface, the second surface of the first substrate adjacent to the first surface of the first encapsulation layer;
a second substrate having a first surface and a second surface opposite to the first surface, the first surface of the second substrate adjacent to the second surface of the first encapsulation layer; and
a third patterned conductive layer disposed on the second surface of the second substrate.

30. The semiconductor package structure of claim 29, wherein the first patterned conductive layer further comprises a plurality of fourth conductive pads, and further comprising a first die electrically connected to the plurality of fourth conductive pads of the first patterned conductive layer.

31. The semiconductor package structure of claim 30, wherein the second patterned conductive layer comprises a fifth conductive pad, and further comprising:
a second die attached to the fifth conductive pad of the second patterned conductive layer through an adhesive layer, wherein an active side of the second die is electrically connected to the second patterned conductive layer via a wire connection.

32. The semiconductor package structure of claim 29, wherein the second patterned conductive layer comprises a fifth conductive pad, and further comprising:
a first die attached to the fifth conductive pad of the second patterned conductive layer through an adhesive layer; and
a second die electrically connected to the first die; wherein the active side of the second die is electrically connected to the second patterned conductive layer via a wire connection, and a second encapsulation layer is disposed between the first die and the second die.

33. The semiconductor package structure of claim 29, further comprising:
a first die electrically connected to the second conductive pad of the first patterned conductive layer;
a second die electrically connected to the first die; and
a second encapsulation layer is disposed between the first die and the second die.

34. The semiconductor package structure of claim 29, further comprising a first die electrically connected to the second conductive pad of the first patterned conductive layer, wherein the first die is encapsulated by a second encapsulation layer.

35. The semiconductor package structure of claim 16, wherein the first patterned conductive layer further comprises a plurality of fourth conductive pads, and further comprising:
a first substrate having a first surface and a second surface opposite to the first surface, the second surface of the first substrate adjacent to the first surface of the first encapsulation layer;
a first die electrically connected to the plurality of fourth conductive pads of the first patterned conductive layer; and
a second die having a back surface and an active surface, the back surface of the second die attached to the first die, and the active surface of the second die electrically connected to a portion of the first patterned conductive layer.

36. The semiconductor package structure of claim 35, further comprising:
a second substrate having a first surface and a second surface opposite to the first surface, the first surface of the second substrate adjacent to the second surface of the first encapsulation layer; and
a third patterned conductive layer disposed on the second surface of the second substrate.

37-62. (canceled)
